(19) United States
(12) Patent Application Publication
(10) Pub. No.: US 2021/0210648 A1
(43) Pub. Date: Jul. 8, 2021

(54) PHOTOVOLTAIC DEVICES BASED ON GUIDED NANOWIRE ARRAYS

(71) Applicant: YEDA RESEARCH AND DEVELOPMENT CO. LTD., Rehovot (IL)

(72) Inventors: Ernesto JOSELEVICH, Rehovot (IL); Eitan OKSENBERG, Rehovot (IL); Regev BEN-ZVI, Rehovot (IL); Jinyou XU, Rehovot (IL); Mark SCHVARTZMAN, Rehovot (IL); Lotem ALUS, Rehovot (IL); Yonatan VERNIK, Rehovot (IL)

(73) Assignee: YEDA RESEARCH AND DEVELOPMENT CO. LTD., Rehovot (IL)

(21) Appl. No.: 17/272,946

(22) PCT Filed: Sep. 5, 2019
(86) PCT No.: PCT/IL2019/051001

§ 371 Date: Mar. 3, 2021

(30) Foreign Application Priority Data
Sep. 6, 2018 (IL) 261680

(51) Int. Cl. H01L 31/0475; H01L 31/0224; H01L 31/0352; H01L 31/072; H01L 31/18

(52) U.S. Cl. CPC H01L 31/0475; H01L 31/022425; H01L 31/18; H01L 31/035281; H01L 31/072; H01L 31/035227

(57) ABSTRACT

This invention relates to photovoltaic devices such as photovoltaic cells and photodetectors. The invention provides processes for fabrication of the devices and methods of use thereof. The invention is further related to controlled growth of nanowire arrays using elongated shapes as guides on the surface.

### FIELD OF THE INVENTION

This invention relates to nanowire (NW) arrays and to photovoltaic devices such as photovoltaic cells and photodetectors. The devices are based on the nanowire arrays. The invention provides processes for fabrication of the arrays and the devices and methods of use thereof.

### BACKGROUND OF THE INVENTION

Autonomous microsystems, including sensor arrays and microrobots, are becoming increasingly important for communications, surveillance and internet-of-things (IoT). Powering such systems is challenging because batteries have large mass and limited energy capacity. Therefore, drawing the energy from the environment becomes necessary. Photovoltaic cells are efficient devices for harvesting the energy from light, but their voltage is normally limited by the energy of photons and internal losses, which reduce their open-circuit voltage to less than 1 V, whereas the voltage necessary to power certain devices can be several volts. This requires the connection of several cells in series, which is difficult to achieve in a reduced size. Core-shell nanowires have been hailed as ideal heterojunctions for photovoltaic cells owing to their reduced radial dimensions, which enable efficient charge separation, and their extended axial dimension, which enables efficient transportation of the separated charges to the electrodes. However, core-shell nanowire arrays have mostly been produced in a vertical configuration, which only enables their integration in parallel, not in series.

### Guided Nanowires

The growth of straight and aligned horizontal nanowires by the guided-growth approach has been demonstrated over the past few years, in view of its potential for the fabrication and study of nanowire-based planar devices. A vapor-liquid-solid (VLS) process, guided by a crystalline surface, yields horizontal nanowires with controlled directions and crystallographic orientations, determined by the epitaxial and grapho-epitaxial relations with the substrate. In epitaxial growth, the guidance occurs along specific lattice directions of a flat surface according to the atomic registry of the nanowire and the underlying substrate. In graphoepitaxy the nanowire grows along nanosteps or nanogrooves and must satisfy both geometrical constraints and lattice constraints with the exposed facets (FIG. 1a). In other words, in graphoepitaxy, both geometry and atomic registry play an important role in guiding nanowires, two guiding factors with an interplay that is not fully understood. This guided growth approach, by either epitaxy or graphoepitaxy, in which both assembly and alignment of nanowires are achieved during the growth process, eliminates the need for post-growth processes and enables deterministic control over the position, direction and length of the nanowires. Although in the last few years it was shown to be useful and general to a large variety of materials and substrates, it is limited to crystalline substrates and yields only straight or randomly kinked nanowires.

### Photovoltaic Cells

The proliferation of electronic devices, especially the growing miniaturized autonomous wireless sensors and networks that promote the world we live in, is increasingly intelligent and calls for the replacement of existing batteries that have to be periodically recharged or replaced. A promising alternative is a compact, inexpensive and highly reliable autonomous energy harvesters, which capture various forms of energy (e.g. thermal, solar, vibration, RF, wind) from ambient environment. Of the main types of miniaturized autonomous energy harvesters, photovoltaic cells made of core-shell nanowires exhibit some unique advantages. For instance, the core-shell nanowire geometry fundamentally enables high photovoltaic performance since it resolves the mismatch between the shorter length scale for minority carrier diffusion and the longer length scale for light absorption by decoupling these directions. More importantly, the monolithic integration of nanowire-based cells would enable multiplied output at micro scale regime, which is critical for some specific applications such as the solar-driven water splitting, ultra-low power electronics (e.g. wristwatches), electrochemical reactions, and next generation of integrated nano-electronics. To date, a great number of nanowire-based photovoltaic cells have been reported, with major effort to race energy conversion efficiency. The vast majority of them are made of individual core-shell nanowire randomly selected from pre-grown nanowires without preferred orientations or from vertical arrays. However, monolithic integration of core-shell nanowires into microscopic photovoltaic modules for small-scale applications were rarely investigated so far. For example, the construction of multi-cell modules, where multiple micro-cells are connected in series to produce high output voltage is complicated. This is because of the need for deterministic assembly of freestanding bottom-up nanowires into desired site-controlled arrays.

While a number of core-shell nanowire vertical arrays have been successfully integrated into parallel modules in the order of a few cubic centimeter size, construction of miniaturized tandem modules from vertical arrays remains a great challenge. Compared with vertical arrays and conventional stacking films, horizontal arrays offer great advantages in simplifying the configuration of tandem photovoltaic cells, as have been demonstrated by the generation of lateral solar cells.

### SUMMARY OF THE INVENTION

It was recently demonstrated that core-shell nanowires can be produced as planar (i.e. horizontal) arrays by surface-guided growth, and act as efficient photovoltaic cells. In this invention it is demonstrated that this planar array configuration of core-shell nanowires enables their efficient integration both parallel and in series. Integration in series multiplies their open-circuit voltage to high, virtually unlimited values. These new miniaturized photovoltaic cells based on guided nanowires integrated in series can be the ideal source for powering autonomous microsystems that require high voltages for operation. The cells can be used to power a variety of microsystems, integrated on the same chip. The high crystallinity of the nanowires produced by guided growth enable fast and highly sensitive photodetectors. Large-scale integration of planar nanowire arrays into photovoltaic cells and photodetectors on glass or other transparent materials can be used to produce smart windows or other photovoltaic-based systems.

This invention provides, in one embodiment, the combination of a vapor-phase surface-guided horizontal nanowire growth at elevated temperature with a solution-processed selective-area cation exchange reaction at moderate temperature to achieve both the synthesis and oriented assembly of core-shell nanowalls (such as n-CdS@p-Cu₂S) in an efficient manner. The position of both the nanowalls themselves and their shells was pre-registered at predictable locations before their formation. Consequently, a scale-up fabrication of micro photovoltaic cells has been achieved without postgrowth transfer, alignment, or selective shell-etching steps. Moreover, these cells are conveniently integrated into miniaturized photovoltaic modules with both parallel and series configurations for the purpose of achieving high output current and voltage at micrometer scale, respectively.

Cu₂S is a p-type semiconductor with an indirect bandgap of 1.2 eV and it serves as an earth-abundant efficient light absorber for photovoltaic applications. Combined with n-type CdS, thin-film Cu₂S-CdS photovoltaic cell has been extensively investigated for planar photovoltaic systems since its first discovery in 1954. However, research interests in Cu₂S-CdS photovoltaic cell, waned during the 1980's due to concerns regarding their long-term stability and of the toxicity of cadmium, as well as the continued progress in silicon and other alternatives. Recently, the interest was renewed by resorting to 1D core-shell nanostructures. For example, a record high open-circuit voltage (0.61 V) and excellent fill factor (80.8%) were documented using single n-CdS@p-Cu₂S core-shell nanowire as a substitution of equivalent thin-film.

In some embodiments, this invention provides an array of nanowires/nanowalls grown on a substrate, wherein:

said substrate is an amorphous substrate; or

said substrate is a polycrystalline substrate;

the long dimension of said nanowires/nanowalls is parallel to the surface of said substrate.

In one embodiment, this invention provides an array of nanowires/nanowalls grown on a substrate, wherein:
said substrate is an amorphous substrate; or
said substrate is a polycrystalline substrate;
the surface of said substrate comprise elongated shapes;
the long dimension of said nanowires/nanowalls is parallel to the surface of said substrate;
the nanowires/nanowalls are located adjacent to said elongated shapes;

wherein said array is produced by a process comprising:
constructing an array of said elongated shapes on said substrate;
applying growth-catalyst material on a region of said elongated shapes;
exposing said substrate to a vapor, said vapor comprising:
   atoms/ions required for nanowire/nanowall formation; and
   carrier gas;
thereby forming said nanowires/nanowalls adjacent to said elongated shapes.

In one embodiment, the nanowires/nanowalls are parallel to each other. In one embodiment, the length of said nanowires/nanowalls ranges between 1 nm and 1000 microns. In one embodiment, the height of the nanowires/nanowalls ranges between 10 nm and 10 microns. In one embodiment, the width of the nanowires/nanowalls ranges between 1 nm and 1 microns. In one embodiment, the height/width aspect ratio of said nanowalls ranges between 50:1. In one embodiment, for a cylindrical NW, the diameter of the NW is in the range specified above for height or for width.

In one embodiment, the nanowires/nanowalls comprise GaN, CdSe, ZnSe, ZnS, CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb₂Te₃, Si, SiC, Ge, InGaN, AlGaN, MAPbX₃ and CsPbX₃ (X=Br, Cl, I). MA is methyl ammonium.

In one embodiment, the spacing between adjacent nanowires/nanowalls of the array ranges between 10 nm and 10 μm.

In one embodiment, the substrate comprises silicon, silicon oxide or silicon coated by silicon oxide.

In one embodiment, the number of nanowires/nanowalls in the array ranges between 1 and 1,000,000 or between 1 and 1,000,000,000.

In one embodiment, at least one of said nanowires/nanowalls is a core-shell nanowire/nanowall or wherein at least one nanowire/nanowall comprises a core-shell section.

In one embodiment, the core comprises CdS and said shell comprises Cu₂S.

In one embodiment, this invention provides a photovoltaic (PV) device comprising:

the array of nanowires/nanowalls grown on a substrate as described herein above, wherein said nanowires/nanowalls comprise a core-shell section;

at least two electrical contacts connected to the wires such that a first contact is connected to the shell of the core-shell section of the wire and a second contact is connected to a non-shelled section of the wire.

In one embodiment, this invention provides a photovoltaic assembly, said assembly comprises at least two PV devices as described herein above.

In one embodiment, in the PV assembly:

the at least two devices are electrically-connected in series such that the positive pole of a first device is connected to the negative pole of a second device; or wherein

the at least two devices are electrically-connected in parallel such that the positive pole of a first device is connected to the positive pole of a second device; or wherein

at least two devices are connected in series and at least two other devices are connected in parallel.

Any combination of parallel and/or series connections of any number of devices is included in embodiments of this invention.

In one embodiment, the output voltage of the device/assembly is at least 0.7 V. In one embodiment, the output voltage of the cell comprising the device/assembly is at least 1V, at least 1.5V, at least 2V or at least 3V, or wherein the output voltage ranges between 1V and 10V, 1V and 100V, 1V and 1000V, 1 V and 100,000V.

In one embodiment, in the photovoltaic device or in the assembly described herein above, the current drawn from the device/assembly under illumination ranges between 1 pA and 1 μA, or between 1 pA and 10 μA, or between 1 μA and 100 μA, or between 100 μA and 10 mA, or between 1 mA and 1A, or between 1 mA and 100A, or between 1 pA and 10 A.

In one embodiment, this invention provides a method of generating voltage, generating current or a combination thereof, said method comprising:

providing the photovoltaic device or the assembly as described herein above;

exposing said device to electromagnetic radiation, thereby generating voltage/current by said cell.

In one embodiment, this invention provides a method of photodetection, said method comprising:

providing a photovoltaic cell or an assembly as described herein above;

exposing the cell to electromagnetic radiation, thereby generating voltage/current by the cell;

using the voltage/current as a detection signal for said radiation.

In one embodiment, this invention provides a method of producing an array of nanowires/nanowalls grown on a substrate, the method comprising:

constructing an array of elongated shapes on the substrate;

applying growth-catalyst material on a region of said elongated shapes;

exposing the substrate to a vapor, the vapor comprising:
atoms/ions required for nanowire/nanowall formation; and
carrier gas;
   thereby forming nanowires/nanowalls adjacent to, or on, or in said elongated shapes.

In one embodiment, this invention provides a method of producing an array of nanowires/nanowalls grown on a substrate, wherein:

said substrate is an amorphous substrate; or

said substrate is a polycrystalline substrate;

the surface of said substrate comprise elongated shapes;

the long dimension of said nanowires/nanowalls is parallel to the surface of said substrate;

the nanowires/nanowalls are located adjacent to said elongated shapes;

said method comprising:
constructing an array of elongated shapes on said substrate;
applying growth-catalyst material on a region of said elongated shapes;
exposing said substrate to a vapor, said vapor comprising:
   atoms/ions required for nanowire/nanowall formation; and
   carrier gas;
      thereby forming nanowires/nanowalls adjacent to, or on, or in said elongated shapes.

In one embodiment, the method further comprises applying shells on a section of said nanowalls/nanowires, thus forming core-shell nanowires/nanowalls on said section.

In one embodiment, the step of applying shells comprises:

protecting sections of the wires using a deposited layer;

exposing the wires to a liquid solution comprising at least one atom/ion of the shell material, thereby forming a shell layer on the unprotected wire section(s).

In one embodiment, the shell layer is formed by cation-exchange reaction.

In one embodiment, the cation exchange reaction is performed in 0.05 M CuCl ammonia solution (25% NH₃) at 50° C.

In one embodiment, the thickness of the shells ranges between 1 nm and 1 micron. In one embodiment, the length of the core-shell section ranges between 10 nm and 1000 microns. In one embodiment, the thickness of the shells ranges between 1 nm and 1 micron and the length of the core-shell section ranges between 10 nm and 1000 microns.

In one embodiment, the shell comprises Cu₂S, CdSe, ZnSe, ZnS, CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb₂Te₃, Si, SiC, Ge, InGaN, AlGaN, MAPbX₃ and CsPbX₃ (X=Br, Cl, I). MA is methyl ammonium.

In one embodiment, the elongated shapes are the guides that guide the nanowires. In one embodiment, the elongated shapes guide the nanowire growth. In one embodiment, the nanowires grow along the elongated shape. In one embodiment, the elongated shapes are referred to as “guides”. In one embodiment, the nanowires/nanowalls are in contact with the elongated shapes.

In one embodiment, the elongated shapes are in the form of grooves, steps, ridges, trenches, channels. In one embodiment, the elongated shapes are in the form of elongated mound, elongated hill, rampart, levee, rise, bank, wall, elongated levee, hillock, elongated elevation. A combination of two or more elongated shapes selected from the shapes described herein above can be present on a substrate.

In one embodiment, the elongated shapes are constructed using photolithography, imprint lithography, electron beam lithography, scratching or any combination thereof.

In one embodiment, the elongated shapes are constructed by mechanical rubbing, scratching or polishing using an abrasive material.

In one embodiment, the dimensions of the elongated shapes are:

height ranging between 5 nm and 10 microns.

width ranging between 10 nm and 10 microns.

length ranging between 10 nm and 1000 microns.

spacing between two adjacent shapes ranging between 10 nm and 10 microns.

In one embodiment, the number of nanowires/nanowalls in the array ranges between 1 and 1,000,000. In one embodiment, the number of nanowires/nanowalls in the array ranges between 1 and 1,000,000,000.

In one embodiment, the elongated shapes are parallel to each other.

In one embodiment, the formed nanowires/nanowalls are parallel to each other.

In one embodiment, this invention provides a method of producing a photovoltaic device, the method comprising:

constructing an array of elongated shapes on a substrate;

applying growth-catalyst material on a region of said elongated shapes;

exposing said substrate to a vapor, said vapor comprising:
atoms/ions required for nanowire/nanowall formation; and
carrier gas;

thereby forming nanowires/nanowalls adjacent to, or on, or in said elongated shapes;

applying shells on a section of said nanowalls/nanowires, thus forming core-shell nanowires/nanowalls on said section;

applying at least two electrical contacts to the device such that a first contact is applied on and is in contact with the shell of a core-shell wire section and a second contact is applied on a non-shelled section of said wire.

In one embodiment, the step of applying shells comprises:

protecting sections of the wires using a deposited layer;

exposing said wires to a liquid solution comprising at least one atom/ion of the shell material, thereby forming a shell layer on the unprotected wire section(s).

In one embodiment, this invention provides a method of producing a photovoltaic device, said method comprising:
constructing an array of elongated shapes on a substrate;
applying growth-catalyst material on a region of said elongated shapes;
exposing said substrate to a vapor, said vapor comprising:
   atoms/ions required for nanowire/nanowall formation; and
   carrier gas;
thereby forming nanowires/nanowalls adjacent to said elongated shapes.
applying shells on a section of said nanowalls/nanowires, thus forming core-shell nanowires/nanowalls on said section;
applying at least two electrical contacts to said device such that a first contact is applied on and in contact with the shell of a core-shell wire section and a second contact is applied on a non-shelled section of said wire;
wherein:
   said substrate is an amorphous substrate; or
   said substrate is a polycrystalline substrate;
   the long dimension of said formed nanowires/nanowalls is parallel to the surface of said substrate;

In one embodiment, the contacts are applied using photolithography and metal evaporation. In one embodiment, an electrical contact area on the substrate/nanowires is defined by photolithography, and this step is followed by metal evaporation into/onto said defined areas. In one embodiment, the metal evaporation forms the desired electrical contact or portions thereof. In one embodiment, the electrical contacts comprise Au or Cr/Au. In one embodiment, the thickness of the contacts ranges between 100 nm and 1000 nm. In one embodiment, a portion of the electrical contacts is deposited in a shape of elongated stripes, the long axis of the stripes is deposited perpendicular to the long axis of the nanowires/nanowalls. In one embodiment, the contacts are connected to a load, to an electrical measurement device or to a combination thereof.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is schematic representation of the three guiding modes: epitaxy, graphoepitaxy and artificial epitaxy; FIG. 1A: straight nanowires are the common outcome of epitaxy (guided growth along flat crystal planes) and graphoepitaxy (guided growth along faceted crystal planes). In artificial epitaxy, nanowires grow along a non-crystalline template and can therefore yield any predesigned shape (FIG. 1B).

FIG. 2 shows guided growth of NWs by artificial epitaxy in open trenches patterned by electron-beam lithography; FIG. 2A is schematic of the EBL fabrication process of open trenches for artificial epitaxy. Patterns are written by EBL in a positive-tone polymer; the exposed areas are washed away upon development. Two processes are employed to create the artificial open trenches: 1) isotropic grooves are wet-etched by BOE at the exposed areas (T1). 2) Anisotropic stripes of amorphous alumina are placed within the exposed areas by electron-beam evaporation (T2). In both cases, after liftoff of unexposed polymer, catalyst patterning is performed, followed by CVD growth of nanowires. FIG. 2B is a scanning electron micrograph of open trenches in a T2 configuration before growth. FIG. 2C shows straight ZnSe nanowires growing in open trenches in a T2 configuration. scale bars are 1 μm.

FIG. 3 shows guided growth of nanowires by artificial epitaxy in open trenches patterned by nanoimprint lithography (NIL); a) schematic of the NIL process. A hard mold with the desired pattern is pressed into a thermoplastic polymer coated on the target substrate and heated above the glass transition temperature (T_{g}). Pneumatic pressure is applied, followed by rapid cooling of the system and separation of the mold and the now plastic, patterned substrate. Throughput is greatly increased with the repeated use of a single master mold; FIG. 3B: open trenches fabricated by NIL in a T1 configuration with 120 nm pitch; in the inset, a cross section of such trenches before growth with 80 nm pitch. The brighter layer is amorphous carbon deposited before the slicing process in the FIB. Inset schematic describes the process of transferring the imprinted pattern to the substrate: first, any polymer remaining in the depressed areas is removed by a gentle RIE. Trenches are prepared by the same two methods described in the EBL process; FIG. 3C straight aligned GaN nanowires growing in open trenches prepared by NIL and alumina evaporation (T2); FIG. 3D: high magnification image of a single GaN nanowire attached to one side of the trench.

FIG. 4 shows NW morphology and crystallinity studied by cross-sectional TEM: FIG. 4A left: low magnification TEM of a cross-section of a ZnSe nanowire guided in a T2 configuration. FIG. 4B right: low magnification TEM of a cross-section of a GaN nanowire guided in a T1 configuration. FIG. 4C left: fringes of the crystal structure of ZnSe observed by HRTEM. inset: FFT. FIG. 4D Right: fringes of the crystal structure of GaN observed by HRTEM. inset: FFT.

FIG. 5 shows guided growth of horizontal nanowires of different materials by artificial epitaxy, growth is guided by various shapes: guided growth of straight (a) CdS, (b) ZnTe and (c) ZnO. Trenches were made by EBL in a T2 configuration. Guided growth of GaN in a (d) sinewave and (e) zigzag shapes. Guided growth of ZnSe in (f) spiral, (g) zigzag and (h) sinewave shapes. Trenches were made by NIL in a T1 configuration. ZnSe nanowires growing in spiral, right angle kinked, and sine wave open trenches patterned by NIL (scale bar 2 μm) d-e) GaN nanowires growing in sinusoidal, right angle kinked and spiral open trenches prepared by nanoimprint lithography (scale bar 1 μm).

FIG. 6 is A) Photo and cathodo-luminescence spectroscopy of ZnSe nanowires grown in sinusoidal open trenches prepared by NIL: a) SEM micrograph of a ZnSe nanowire grown in a sinusoidal open trench b) PL hyperspectral map of the nanowire in (a); the color change corresponds to variations in wavelength. c) point by point CL map overlaid on the corresponding SEM micrograph; the color change corresponds to variations in wavelength (scalebars 1 μm). B) Photoluminescence spectroscopy of GaN nanowire grown in sinusoidal open trenches prepared by NIL: a) SEM micrograph of a GaN nanowire grown in a sinusoidal open trench. b) PL intensity map of the nanowire in (a); c) PL hyperspectral map of the nanowire in (a); the color change corresponds to variations in wavelength.

FIG. 7 illustrates schematics of open trenches fabrication by NIL and wet-etch: a) PMMA imprint resist is spin coated on a Si/SiO₂ (300 nm) wafer. b) The master mold is pressed into the PMMA. c) The sample after separation from the mold. d) The residual PMMA is etched by a gentle reactive ion etching. e) The SiO₂ layer is etched by BOE f) Liftoff of remaining resist.

FIG. 8 illustrates schematics of open trenches fabrication by NIL and Al₂O₃ evaporation: a) PMMA imprint resist is spin coated on a Si/SiO₂ (300 nm) wafer. b) The master mold is pressed into the PMMA. c) The sample after separation from the mold. d) Angle evaporation of Ti; e) the residual PMMA is etched by a gentle reactive ion etching. f) electron-beam evaporation of Al₂O₃; g) Liftoff of remaining resist.

FIG. 9 shows mold patterning with hydrogen silsesquioxane (HSQ).

FIG. 10 shows ZnO growth on lithographic open trenches: a) SEM top view of ZnO after CVD. Trenches are fabricated by NIL followed by wet etch (T1). b) Cross-sectional TEM of the same sample. Lamella was made by FIB c) Zoom in on a single structure. ZnO in observed as a thin layer on top of the SiO₂ peak. Inset: EFTEM taken on additional structure showing Zn in magenta and Si in turquois d) ZnO growth in sine-wave shaped trenched (T1) e) additional ZnO growth in straight trenched (T1).

FIG. 11 is a photoluminescence image of sine-wave shaped GaN nanowire.

FIG. 12 is a schematic illustration of experimental steps for forming a core-shell device. (a) Selective deposition of gold pads on the annealed M(101̅0) sapphire surface. (b) Site-controlled growth of self-aligned CdS horizontal nanowires. (c) Deposition of Al₂O₃ mask layer over whole substrate. (d) Define the region to be etched by photolithography. (e) Selective-area etching of Al₂O₃ mask layer. (f) Photoresist lift-off. (g) Cation exchange reaction. (h) Second etching of remained Al₂O₃ mask layer. Inset shows the red segments are core-shell nanowires. (i) Predictable electrode deposition.

FIG. 13 shows characterization of n-CdS@p-Cu₂S core-shell nanowalls. (a) SEM of as-grown CdS nanowalls. The dashed rectangle indicated the catalyst pad position before the growth. Zoom-in view (inset) shows the nanowall geometry. (b) Cross-sectional TEM of the CdS@Cu₂S segment. (c) Corresponding 2D EELS mapping for Cd, Cu, and S elements, respectively. (d) Bright-field optical image under illumination of 405-nm laser light. The image is taken with a 405-nm notch filter. (e) Intensity-normalized PL spectra from the CdS-only segments before (purple) and after (cyan) the cation exchange reaction. (f, i) TEM images near the CdS-sapphire interface and the CdS-Cu₂S edge, respectively. Insets are their FFT patterns. (g, j) Simulated FFT patterns for the area shown in panel (f) and (i), respectively. (h) Inverse FFT image for the [011̅1̅]_{CdS}∥[1̅102]_{Al}_{₂}_{O}_{₃} , diffraction spot. The yellow arrows indicate the locations of misfit dislocations. Inset highlights one misfit dislocation. (h) Inverse FFT image for the [101̅1̅]_{CdS}∥[101̅1̅]_{Cu}_{₂}_{S} diffraction spot.

FIG. 14 shows scale-up fabrication and characterization of photovoltaic cells based on n-CdS@p-Cu₂S core-shell nanowall horizontal arrays. (a) SEM. Region-I includes many independent cells, each made of a few parallel nanowalls from the same catalyst pad, Region-II and Region-III are cell modules connected in series and in parallel, respectively. The yellow dashed lines indicate the boundary between different regions. Inset shows corresponding digital photograph. False color was added to highlight the different regions. The scale bar is 2 mm. (b) SEM of a representative photovoltaic cell. False color was added onto one nanowall to show the CdS-only segments (yellow) and the CdS@Cu₂S core-shell segment (cyan, between the dashed lines). (c) I-V curves of the device with contacts on core-core (n1-n2), core-shell (n2-p2) and shell-shell (p1-p2) configuration under 1 sun (AM 1.5G) illumination. (d) Plot of output current and power as a function of voltage for the cell made of 9 parallel nanowalls (n2-p2), under 1 sun illumination. FF is defined as the maximum power (yellow area) divided by the product of I_{sc} and V_{oc} (light blue area). (e) Cell I-V curves with increasing light intensity. (f) Light intensity dependence of I_{sc} and V_{oc} for the same cell.

FIG. 15 shows monolithic integrated photovoltaic modules based on n-CdS@p-Cu₂S core-shell nanowall horizontal arrays. (a, b) SEM of cell modules in series and in parallel configuration, respectively. False color was added to show the electrodes. (c, d) I-V characteristic and corresponding V_{oc} of the series-connected cell modules under 1 sun (AM 1.5G) illumination, showing that the V_{oc} is additive and the I_{sc} remains fixed. (e, f) I-V characteristic and corresponding I_{sc} of the parallel-connected cell modules under 1 sun (AM 1.5G) illumination, showing that the I_{sc} is additive and the V_{oc} remains fixed.

FIG. 16 is 45°-tilted SEM image of as-grown CdS nanowalls. Inset shows the nanowall is aligned along the nanogroove.

FIG. 17 is an SEM image of CdS-Cu₂S nanowalls on annealed M(101̅0) sapphire.

FIG. 18 is EDS spectra recorded from different regime.

FIG. 19 is a TEM image of the nanowall with height-to-width up to 14. The height and width are 490 nm and 35 nm, respectively.

FIG. 20 shows optical microscope photographs recorded with different modes. (a) Bright-field without laser illumination. (b) Dark-field without laser illumination. (c) Dark-field with laser illumination. (d) Real-color emission image under laser illumination without background light.

FIG. 21 is a logarithmic re-plot of the I-V curve recorded with contacts on the core-shell (n2-p2) configuration (FIG. 13C, purple) under 1 sun illumination.

FIG. 22 schematically shows growth of nanowires on a scratched amorphous surface; left-amorphous surface before scratching; middle-scratched surface; right-nanowires grown in/on the scratches.

FIG. 23 shows a scratched substrate; left: AFM image showing the scratches; sample was polished using ˜20 N force; sample size was 5 mm×10 mm; right: sample height profile along the line depicted in the AFM image on the left.

FIG. 24 top: SEM image showing nanowires grown on an amorphous substrate; the bar in the middle is a gold bar used as nucleation for nanowire growth; bottom: schematics of the nanowire CVD growth process.

FIG. 25 comparison of single crystal substrate, annealed M plane sapphire (top) with the scratching of an amorphous substrate (bottom).

FIG. 26 shows growth of CdS, II-IV SC nanowires on a Si/SiO₂ substrate, 300 nm thermal oxide layer; growth initiated from 5 Å Au thin film; FIG. 26A SEM image showing the grown NW's; FIG. 26B higher magnification SEM image showing a nanowire region; FIG. 26C 3D AFM image showing the nanowalls structure; FIG. 26D Magnification of a CdS NW edge, SEM; FIG. 26E photoluminescence spectra of a single nanowire.

FIG. 27 shows focused ion beam transmission electron microscope (FIB-TEM) imaging and analysis; FIG. 27A FIB-TEM image of the NW's grown on the substrate; FIG. 27B-FIG. 27D are cross-sectional TEM images of nanowires on the substrate; wires are cadmium sulfide (CdS, II-VI SC) grown on Si/SiO₂ substrates.

FIG. 28 shows elemental analysis images supporting the chemical composition of the NWs; FIG. 28A shows the shows composition of the various elements; FIG. 28B highlights each element separately (Cd, S, O, Si, Pt and C).

FIG. 29 TEM images and data showing growth of cadmium sulfide (CdS, II-VI SC) NWs on Si/SiO₂ substrates; crystallographic analysis supports a single crystal structure; FIG. 29A is for NW 1; FIG. 29B is for NW 2.

FIG. 30 growth of zinc selenide (ZnSe, II-VI SC) NWs on scratched Si/SiO₂ substrates, 300 nm thermal oxide layer; NWs are grown from a solution deposited on the surface in drops and dried. The solution is 1% Au in H₂O (0.5% 20 nm NPs+0.5% 50 nm NPs) 1% volume Au solution in volume water (v:v); FIG. 30A SEM image; FIG. 30B higher magnification SEM image; FIG. 30C photoluminescence spectra of a nanowire.

FIG. 31 scratched glass (microscope slide, ˜20 N, 15 sec, 30 μm diamonds); FIG. 31A before annealing; FIG. 31B after annealing at 600° C. for 30 min; FIG. 31C photograph of the slide.

FIG. 32 CdS NWs on scratched microscope slide (Thermo-scientific sandblasted single frosted, Cat. No 421-004T, 25 mm×75 mm×1 mm slide); FIG. 32A SEM images of CdS NWs catalyzed with 5% Au NP solution in H₂O v:v (image shows growth from droplets' rim) 0.7 μL drop followed by ashing at 550° C. for 7 min; FIG. 32B shows SEM image showing the alignment of the NWs within the scratches; FIG. 32C optical microscope image (×100) of CdS catalyzed by 5% Au NPs solution in H₂O (image is taken inside the droplet area); FIG. 32D: 2D FFT of the image in FIG. 32C.

FIG. 33 CdS NWs on scratched microscope slides illuminated by white light and by UV light (405 nm laser).

FIG. 34 illustrates alumina-to-glass imprinting process;

FIG. 35 FIG. 35A is a photograph showing the annealed sapphire attached to the surface of a glass; the two substrates are placed between two quartz slides; FIG. 35B shows the same structure with a weight on top;

FIG. 36 FIG. 36A is an SEM image of a microscope slide before imprinting; FIG. 36B is an SEM image showing the microscope slide following imprint.

FIG. 37 FIG. 37A is an SEM image of an annealed M-plane sapphire surface used for imprinting on glass; FIG. 37B is an SEM image of a microscope slide following imprint using the M-plane sapphire.

FIG. 38 FIG. 38A to FIG. 38C are SEM images of samples of glass surfaces imprinted at various imprinting temperatures (FIG. 38A at 590° C., FIG. 38B at 600° C., FIG. 38C at 610° C.).

FIG. 39 sample is a microscope slide imprinted using grooved sapphire, 5 Å Au evaporation for the formation of Au centers for NW growth. FIG. 39A is an SEM image showing guided growth of CdS nanowires & nanowalls on glass; FIG. 39B is a magnification of the red dashed line in FIG. 39A, showing the alignment of the nanowires along the imprinted nanogrooves;

FIG. 40 guided growth of CdS nanowires & nanowalls on soda-lime glass from gold nanoparticles, sample is microscope slide. The gold nanoparticles are deposited from a solution comprising 50 nm gold nanoparticles, solution is 1% NP suspension in water v:v (volume:volume): FIG. 40A is an SEM image showing guided growth of CdS nanowires; FIG. 40B an SEM image of another area showing guided growth of CdS nanowires.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In one embodiment, this invention provides photovoltaic devices. The photovoltaic devices of this invention comprise core-shell nanowires or nanowalls. The nanowires/nanowalls are grown horizontally on amorphous substrates (or on polycrystalline substrates), thus providing low-cost construction and compatibility with Si technologies. The planar configuration of the devices on a substrate allows integration of a plurality of devices in series and/or in parallel. Such integration enables implementation of desired electrical properties such as high voltage/high current output. Devices of this invention can be used in many applications including but not limited to solar cells and photodetectors. Devices of this invention can be incorporated in larger electronic and/or optical systems.

### Guided Nanowires by Artificial Epitaxy

In one embodiment, this invention demonstrates guided growth of horizontal nanowires along straight, curved, angled and arbitrarily shaped amorphous nano lithographic open trenches.

In one embodiment, nanoimprint lithography (NIL) is used as a high throughput method for the fabrication of high-resolution features. As exemplified herein, five different semiconductor materials (GaN, ZnSe, CdS, ZnTe and ZnO) were grown along straight open trenches with either curved or sharp cross-section, demonstrating the generality of this method. Through crystallographic analysis it was found that despite the absence of any epitaxial relations with the substrate, the nanowires grow in preferred crystallographic orientations. ZnSe and GaN were grown also along curved and kinked configurations to form, for example, sinusoidal and zigzag-shaped nanowires. While all nanowires are elongated by a vapor-liquid-solid mechanism, chalcogenide nanowires also show vapor-solid growth that leads to tapering. This phenomenon is more pronounced in the shaped nanowires than in the straight ones. Photoluminescence and cathodoluminescence were used as a noninvasive tool to characterize sinewave-shaped nanowires. With no vapor-solid growth, photoluminescence mapping of sinewave-shaped GaN, shows red-shift of the near band-edge emission in areas with higher curvature, indicating a strain-induced band gap shrinking. Sinewave shaped ZnSe nanowires with significant vapor-solid growth show variation in the near band-edge emission along them, but with no correlation to the curved geometry of the nanowire.

The opportunity to expand the guided growth approach to the growth of nanowires with controlled shapes on amorphous substrates is clearly attractive from a technological point of view, enabling the creation of specialized devices, such as unique configurations of optical waveguides and electric circuits. Moreover, the ability to eliminate the use of a crystalline substrate opens the possibility to use a much larger variety of substrates such as, flexible substrates and the common oxidized silicon wafers, which allows back gate configuration in nanowire-based field effect transistors. From a more scientific point of view, guided growth along amorphous features provides the opportunity to study the role of the geometric constrain, while completely excluding the effect of epitaxy. Thus, it might shed light on the interplay between the effect of geometry and atomic registry in guided growth of nanowires by graphoepitaxy. However, the expansion of the guided growth approach beyond crystallographic guidance of straight nanowires is not trivial. More specifically, it is questioned if geometry is enough to guide the growth of horizontal nanowires, and if so, what would be the effect on their morphology and crystallinity. In addition, the possibility to guide nanowires along arbitrary shapes is explored. Growing nanowires with predesigned curvature can be used for the study of strain related effects on crystallinity and properties of nanowires from different materials. It was demonstrated that when vertically grown nanowires are bent or curved after growth, a red-shift of the NBE emission is observed in the points with higher curvature along the nanowire, indicating a strain related decrease of the band-gap. However, nanowires growing along curved features might differ from nanowires under post growth straining and the effect on the optical properties in this case is yet to be studied.

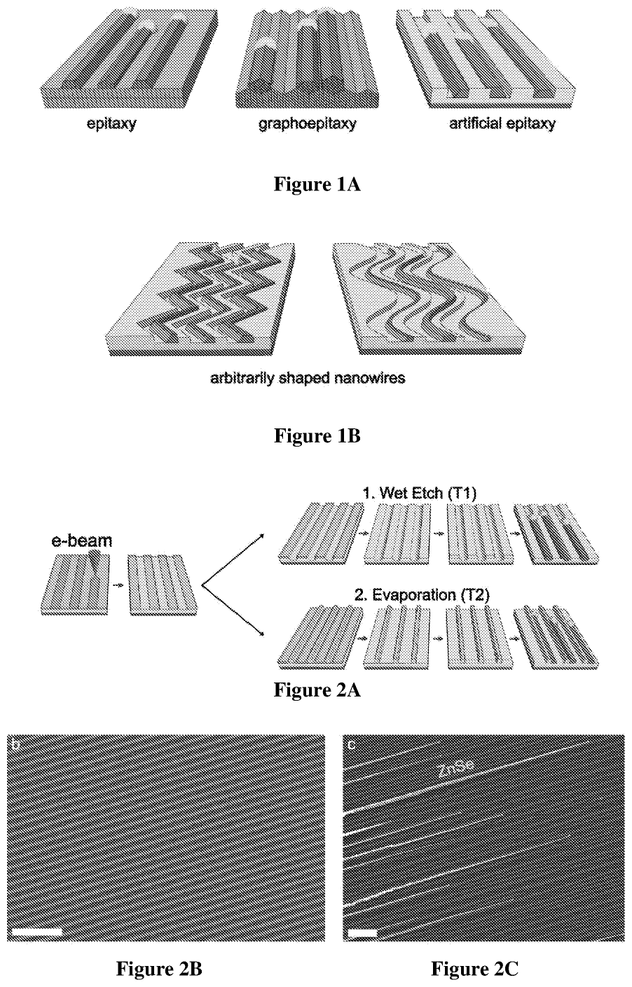

The concept of using amorphous lines as nucleation sites and growth guides is termed artificial epitaxy. The idea is very similar to the scratching of a glass beaker in order to induce and guide recrystallization processes. In artificial epitaxy, growth occurs along some lithographic template on an amorphous substrate by geometric guidance alone. In the past, such growth was found to be rather challenging; in fact, the first attempts to guide GaN nanowires along templates patterned by photolithography failed, primarily due to the limitations of the lithographic technique. The microscale dimensions of the templates were too large, their features too rough, and their density too sparse for successful guidance of nanowires. It is now found that these limitations can be overcome by using higher resolution lithographic techniques, such as electron-beam lithography (EBL) and in principle, the template can be of any arbitrary pattern (FIG. 1B). A non-epitaxial, in-plane guided shaping of nanowires is possible by several lithographic techniques. For example, the VLS growth of Si and Ge nanowires in pre-defined shapes was demonstrated by confining the growth in closed channels created by EBL followed by multiple fabrication steps. The growth in this case is limited by the diffusion into the closed channel and the size and shape of the nanowire is determined by the dimensions and quality of the channel. Alternatively, nanowires can be guided along the edges of a shaped open trench, as previously demonstrated and it presents high crystallinity. However, this process was specifically developed for the solid-liquid-solid growth of Si nanowires and not for the general growth of nanowires from different materials.

A different approach for creating nanowires with different geometries is based on post growth shaping and usually involves placement of vertically grown nanowires along some lithographic pattern, such as anchors that result in u-shaped nanowires, or scaffolding that results in periodically strained nanowires. These techniques offer only partial control over geometry and lack the abovementioned advantages of the guided growth method. More specifically, since post growth manipulations and transfer of nanowires is required, these methods are more prone to fracture and contamination of the nanowires. 3D and in-plane buckled nanowires can be achieved by transferring them onto a pre-strained elastomer and releasing the tensile strain. In principle, this method can be applied to any nanowire material but is limited to a specific “wavy” geometry. To truly expand the guided growth approach of nanowires, a high-throughput method that is not limited to specific material and geometry is required.

In one embodiment, this invention demonstrates the growth of semiconductor nanowires along open nanolithographic trenches on the amorphous thermal oxide layer of a silicon wafer by artificial epitaxy. Guided growth of NW along straight lines in open amorphous trenches is demonstrated by methods of this invention. Nanowires of several material systems (GaN, ZnSe, CdS, ZnTe and ZnO) were successfully grown within these open trenches, which were initially patterned by EBL. In another embodiment, this serial process was substituted with nanoimprint lithography (NIL) patterning, demonstrating a fully parallel (i.e. high-throughput) patterning process. Another patterning technique employed was scratching of the amorphous surface to form open trenches. Two different cross-sections were examined for the guiding open trenches: smooth curved trenches, and a 90° profile trenches. The morphology of ZnSe and GaN nanowires growing in the two different templates has been characterized by cutting thin, electron-transparent slices across the nanowires with a focused-ion beam (FIB) and observing them under a transmission electron microscope (TEM). The quality and crystallographic orientation of the nanowires has been characterized by using a high resolution TEM. Surprisingly, despite the lack of epitaxial relations, preferred crystallographic orientations have been found for both ZnSe and GaN nanowires. Using NIL, various curved and kinked designs have been introduced, for synthesizing nanowires of arbitrary and controlled shapes (spiral, zigzag and sinusoidal shape). The nanowire shapes can be controlled by the substrate features and geometry. Specifically, sine-wave shaped ZnSe and GaN nanowires are compared and show pronounced VS growth, and no VS growth, respectively. Photoluminescence (PL) and cathodoluminescence (CL) mapping are performed as non-invasive characterization techniques and show shifts in the near band edge (NBE) emission along the nanowires. While in ZnSe these changes do not correlate with the sinusoidal geometry of the shaped nanowire, and are likely due to VS growth, in GaN, a red-shift in PL emission is correlated with higher curvature areas, suggesting strain-induced reduction of the band-gap. This combination of top-down and bottom-up approaches can be applied for large-scale fabrication and study of predesigned shapes of nanowires from different materials.

### Photovoltaic Cells

One-dimensional (1D) core-shell nano structures have been recognized as attractive building blocks for developing micro energy harvesters to replace the widely used batteries in the rapidly growing miniaturized autonomous wireless electronics. However, their deterministic assembly into horizontal arrays for monolithic integration of photovoltaic cell remains a major challenge. This invention provides in one embodiment, direct synthesis of self-aligned core-shell nanowalls (such as n-CdS@p-Cu₂S) with site- and length-controlled shells by a combination of surface-guided horizontal growth and selective-area solution-processed cation exchange reaction. Such horizontal arrays enable a scale-up straightforward implementation of photovoltaic cells, without postgrowth transfer, alignment, and selective shell-etching steps. The open-circuit voltage (V_{oc}) of individual cell made of a few parallel nanowalls is up to 0.7 eV, a new record for CdS-Cu₂S photovoltaic cells. Even more impressive, these cells were connected into multiple-cell modules with dimension down to the microscale regime, which has rarely been investigated based on bottom-up nanowires. A large V_{oc} of 2.5 V was observed for the modules made of 4 cells connected in series, accompanied with matched fill factors and short-circuit currents. The energy conversion efficiency of these cells was found to be (<2.5%). However, the capability of producing microscopic tandem cell modules for high V_{oc}, has potential applications in the upcoming nano-electronics and the growing miniaturized autonomous wireless electronics. The proposed route is fundamentally applicable to other 1D core-shell nano structures, and it opens new opportunities for direct scale-up synthesis of site-controlled core-shell nanostructure horizontal arrays toward monolithic integration of photovoltaic cell, especially the microscopic multi-cell modules.

In one embodiment, this invention provides guided nanowires with arbitrary shapes grown by artificial epitaxy along lithographic open trenches. In one embodiment, this invention provides monolithic integration of photovoltaic cells based on site-controlled n-CdS@p-Cu₂S Core-Shell nanowall horizontal arrays.

Nanowalls in one embodiment are nanowires with cross-section aspect ratio wherein the height is larger than the width of the nanowire. In some embodiments where reference is made to a nanowire, the embodiment also refers to a nanowall. NW refers to nanowire(s) and in some embodiments to nanowalls as well.

Hydrogen silsesquioxane (HSQ) is used in some embodiments as the electron-beam resist. HSQ is used to achieve high resolution features due to its low line-edge roughness and low molecular weight.

In some embodiments, multiple-cell modules are modules where multiple semiconductor materials are used to absorb a broader range of energies in order to produce high output voltage. In other embodiments, multiple-cell means any combination of more than one cell, e.g. an assembly of two or more cells.

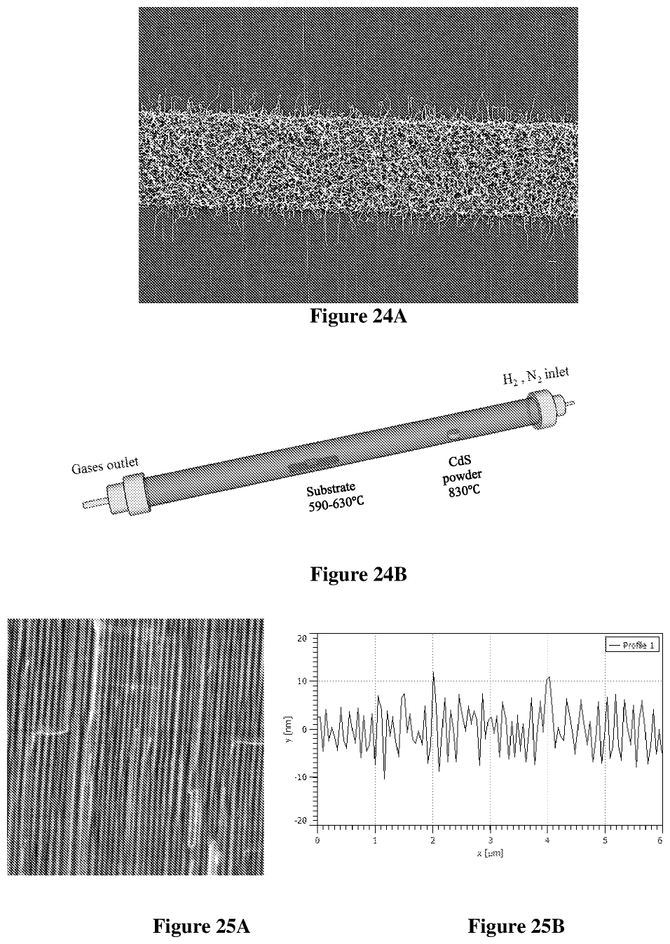

Different nanowire/nanowall growth parameters are used for different materials. In general, and according to some embodiments, growth is done in a quartz tube that is placed in a furnace. A powder of the relevant material is placed in a crucible and a sample is placed downstream (see for example FIG. 24). Temperature is controlled separately on the crucible and on the sample. N₂ is used as a carrier gas. For some materials other gases or additional gasses are used.

In some embodiments, pitch means the distance or separation between trenches. In some embodiment, pitch is the separation between trenches, between elongated structures, between parallel nanowires etc. as known in the art.

In some embodiments, for TEM measurements, the lamellea used were ˜70 nm thick. In some embodiments, the lamellea are transparent to electron-beams as required for the TEM measurements.

In some embodiments, in (vapor liquid solid) VLS processes, material from the gas phase is dissolved in a catalyst droplet and when it reaches supersaturation it crystalizes, and the nanowire begins its growth. In some embodiments, in vapor solid (VS) processes, material from the gas phase directly nucleates on the nanowire, contributing to the formation of tapered nanowires and nanowalls.

In some embodiments, the trenches, the elongated structures, the elevated structures, the etched structures or any combination thereof and the nanowires grown in/at/near/on them, are of arbitrary shape. In some embodiments, the elongated structures/nanowires are straight, curved, sinusoidal-like, non-symmetric, partially-symmetric, round, triangular, rectangular, angled, comprise right angles, or comprise or consist of any other shape that fits certain applications or uses.

In some embodiments, nanowires/nanowalls of this invention were grown from GaN, CdSe, ZnSe, CdS, ZnTe or from ZnO. In some embodiments, nanowires/nanowalls of this invention are grown from ZnS or from CsPbBr₃.

In some embodiments, in materials of the invention, MA stands for methylammonium, e.g. in MAPbX₃, MA is methyl ammonium.

Nanowires: nanowires are non-hollow solid elongated structures. Nanowires are different from nanotubes which are hollow structures. Moreover, nanowires of the present invention are crystals of nanometer-scale diameters having nearly the same structure as a bulk crystal of the same composition. This is in contrast to carbon nanotubes which are made of one or several layers of a two-dimensional material that are curved and rolled up as a tube. The interaction between nanowires of the present invention and a substrate are different from the interaction of carbon nanotubes and a substrate. The interaction between carbon nanotubes and a substrate is a weak interaction based on van der Waals forces. In contrast, the interaction between nanowires of the present invention and a substrate is stronger and could be based on covalent bonds and/or ionic bonds in some embodiments. The growth parameters of nanowires of the present invention are different from the parameters used for the formation of carbon nanotubes. The precursor materials are different and for NW growth they are provided initially in a solid form. Nanowires and nanotubes are two different classes of nano structures.

Elongated shapes are sometimes referred to as ‘guides’ in embodiments of this invention. This is because the elongated shapes guide the growth of the nanowires. The nanowire growth is guided by the elongated shapes. The term ‘elongated shapes’ is also substituted with the term ‘elongated structures’ in some embodiments. These two terms are interchangeable.

The term ‘substrate’ refers to the top-most portion of a material on which the elongated shapes and the nanowires are grown. In some embodiments, the substrate comprises one material. In some embodiments, the substrate comprises two or more layers of materials. According to this aspect and in one embodiment, the top-most layer, or all the layers together is/are considered as ‘the substrate’. When a coating layer covers a substrate, this coating layer is considered part of the substrate and is referred to as ‘substrate’ in some embodiments. For example, a Si coated by a layer of SiO₂ is considered a substrate. The coating SiO₂ layer is also regarded as ‘substrate’ in some embodiments. In some embodiments, the term ‘surface’ is used. The ‘surface’ is the surface of the substrate. The elongated shapes and the nanowires are grown on or in or adjacent to the elongated shapes on the surface of the substrate. The terms ‘surface’ and ‘substrate’ are interchangeable in some embodiments.

In one embodiment, the nanowires/nanowalls are located adjacent to said elongated shapes. In one embodiment, adjacent means that the nanowires are in contact with the elongated shapes. In one embodiment, adjacent means next to the elongated shapes, in or partially in the elongated shapes, on or partially on the elongated shapes, at the side of the elongated shapes or a combination thereof. In one embodiment, adjacent means that the nanowires follow the contour of the elongated shapes. The path of the nanowire is close to the path of the elongated shape throughout the length of the nanowire or throughout the length of a portion of a nanowire in one embodiment. In one embodiment, the elongated shape and the nanowire are side-by-side.

### Embodiments of Nanowire Arrays and PV Devices

An array of nanowires/nanowalls grown on a substrate, wherein:
said substrate is an amorphous substrate; or
said substrate is a polycrystalline substrate;
the surface of said substrate comprise elongated shapes;
the long dimension of said nanowires/nanowalls is parallel to the surface of said substrate;
the nanowires/nanowalls are located adjacent to said elongated shapes;
   wherein said array is produced by a process comprising:
constructing an array of said elongated shapes on said substrate;
applying growth-catalyst material on a region of said elongated shapes;
exposing said substrate to a vapor, said vapor comprising:
atoms/ions required for nanowire/nanowall formation; and
carrier gas;
   thereby forming said nanowires/nanowalls adjacent to said elongated shapes.

In one embodiment, the nanowires/nanowalls are parallel to each other.

In one embodiment, the length of said nanowires/nanowalls ranges between 1 nm and 1000 microns. In one embodiment, the height of the nanowires/nanowalls ranges between 10 nm and 10 microns. In one embodiment, the width of the nanowires/nanowalls ranges between 1 nm and 1 microns. In one embodiment, the height/width aspect ratio of said nanowalls ranges between 50 and 1.

In one embodiment, the nanowires/nanowalls comprise GaN, CdSe, ZnSe, ZnS, CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb₂Te₃, Si, SiC, Ge, InGaN, AlGaN, MAPbX₃ and CsPbX₃ (X=Br, Cl, I).

In one embodiment, the spacing between adjacent nanowires/nanowalls of the array ranges between 10 nm and 10 μm.

In one embodiment, the substrate comprise silicon, silicon oxide or silicon coated by silicon oxide. In one embodiment, the substrate is glass.

In one embodiment, the number of nanowires/nanowalls in the array ranges between 1 and 1,000,000 or between 1 and 1,000,000,000.

In one embodiment, at least one of said nanowires/nanowalls is a core-shell nanowire/nanowall or wherein at least one nanowire/nanowall comprises a core-shell section.

In one embodiment, the core comprises CdS and said shell comprises Cu₂S.

In one embodiment, this invention provides a photovoltaic (PV) device comprising:
a nanowire array as described herein above wherein said nanowires/nanowalls comprise a core-shell section;
at least two electrical contacts connected to the wires such that a first contact is connected to the shell of the core-shell section of the wire and a second contact is connected to a non-shelled section of the wire.

In one embodiment, this invention provides a photovoltaic assembly, said assembly comprises at least two PV devices as described herein above.

In one embodiment, this invention provides a photovoltaic assembly as described herein above, wherein:
said at least two devices are electrically-connected in series such that the positive pole of a first device is connected to the negative pole of a second device; or wherein
said at least two devices are electrically-connected in parallel such that the positive pole of a first device is connected to the positive pole of a second device; or wherein
At least two devices are connected in series and at least two other devices are connected in parallel.

In one embodiment, the output voltage of said device/assembly is at least 0.7V.

In one embodiment, the output voltage of said cell is at least 1.5V, at least 2V or at least 3V, or wherein the output voltage ranges between 1V and 10V, 1V and 100V, 1V and 1000V, 1 V and 100,000V.

In one embodiment, the current drawn from the device under illumination ranges between 1 pA and 1 μA or between 1 pA and 10 μA, or between 1 μA and 100 μA, or between 100 μA and 10 mA, or between 1 mA and 1 A, or between 1 mA and 100 A.

In one embodiment, this invention provides photovoltaic devices with high voltage output.

### Methods of Use of the Nanowire Arrays

In one embodiment, this invention provides a method of generating voltage, generating current or a combination thereof, the method comprising:
providing the photovoltaic device or the assembly as described herein above;
exposing said device to electromagnetic radiation, thereby generating voltage/current by said cell.

In one embodiment, the electromagnetic radiation is light. In one embodiment, the electromagnetic radiation is sun light.

In one embodiment, this invention provides method of photodetection, said method comprising:
providing a photovoltaic cell or an assembly as described herein above;
exposing the cell to electromagnetic radiation, thereby generating voltage/current by said cell;
using said voltage/current as a detection signal for said radiation.

### Methods of Producing Nanowire Arrays

In one embodiment, this invention provides a method of producing an array of nanowires/nanowalls grown on a substrate, wherein:
said substrate is an amorphous substrate; or
said substrate is a polycrystalline substrate;
the surface of said substrate comprise elongated shapes;
the long dimension of said nanowires/nanowalls is parallel to the surface of said substrate;
the nanowires/nanowalls are located adjacent to said elongated shapes;

said method comprising:
constructing an array of elongated shapes on said substrate;
applying growth-catalyst material on a region of said elongated shapes;
exposing said substrate to a vapor, said vapor comprising:
   atoms/ions required for nanowire/nanowall formation; and
   carrier gas;
thereby forming nanowires/nanowalls adjacent to, or on, or in said elongated shapes.

In one embodiment, nanowire growth is guided by the elongated shapes. In one embodiment, nanowire growth is initiated by the growth catalyst. In one embodiment, nanowire growth starts at the region where the growth catalyst is present. In one embodiment, nanowire growth starts from the growth catalyst and it is further proceeds along the elongated shapes. In one embodiment, the growth catalyst allows for initiation of the nanowire growth, while the elongated shapes direct the growth of the nanowire. The contour of the elongated shapes dictates the contour of the nanowire that grows next to it.

In one embodiment, the method further comprising applying shells on a section of said nanowalls/nanowires, thus forming core-shell nanowires/nanowalls on said section.

In one embodiment, the step of applying shells comprises:

protecting sections of the wires using a deposited layer;

exposing the wires to a liquid solution comprising at least one atom/ion of the shell material, thereby forming a shell layer on the unprotected wire section(s).

In one embodiment, the shell layer is formed by cation-exchange reaction. In one embodiment, the nanowire growth is conducted from a vapor phase while the shell growth is conducted from a liquid phase.

In one embodiment, the cation exchange reaction is performed in 0.05 M CuCl ammonia solution (25% NH₃) at 50° C.

In one embodiment, the thickness of said shells ranges between 1 nm and 1 micron; and the length of said core-shell section ranges between 10 nm and 1000 microns.

In one embodiment, the thickness of the shells ranges between 1 nm and 1 micron. In one embodiment, the length of the core-shell section ranges between 10 nm and 1000 microns.

In one embodiment, the shell comprises Cu₂S, CdSe ZnSe, ZnS CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb₂Te₃, Si, SiC, Ge, InGaN, AlGaN, MAPbX₃ and CsPbX₃ (X=Br, Cl, I).

In one embodiment, the nanowires/nanowalls are in contact with said elongated shapes.

In one embodiment, the elongated shapes are in the form of grooves, steps, ridges, trenches or channels. In one embodiment, the elongated shapes are constructed using photolithography, imprint lithography, electron beam lithography, surface scratching or any combination thereof.

In one embodiment, the elongated shapes are constructed by mechanical rubbing, scratching or polishing using an abrasive material. According to this aspect and in one embodiment, the elongated shapes are formed by scratching a material such as glass or Si coated by SiO₂. In one embodiment, scratching is performed using diamond particles. In one embodiment, scratching is conducted on a polishing wheel. According to this aspect and in one embodiment, the scratching of glass or of SiO₂ on Si or of any other substrate is conducted as follows:

cloth is attached to the wheel of a polishing machine;

cloth is soaked with water;

the cloth is sprayed with a diamond suspension;

the suspension is dispersed with water while rotating the wheel;

the glass or Si/SiO₂ substrate is attached to an edge of the cloth;

the substrate is polished by rotation of the wheel.

In one embodiment, the dispersion step is performed at 250 rpm wheel-rotation speed. In one embodiment, the dispersion step is performed at 50 rpm to 1000 rpm wheel rotation speed. In one embodiment, the polishing step is performed at 250 rpm wheel rotation speed. In one embodiment, the polishing step is performed at 50 rpm to 1000 rpm wheel rotation speed. In one embodiment, the polishing step is performed for a period of 10-20 sec. In one embodiment, the polishing step is performed for a period of 5-60 sec.

In one embodiment, following polishing, the substrate is sonicated in a liquid bath. In one embodiment, the substrate is sonicated in two or more solvents consequently. In one embodiment, the substrate is sonicated in acetone, followed by sonication in IPA (isopropanol) and concluded with sonication in water. Sonication disposes left-overs of diamond or diamond suspension materials. Sonication cleans the substrate in one embodiment. In one embodiment, the force by which the substrate is attached to the cloth can be varied. In one embodiment, the substrate is attached to the cloth using force varying between 0.5 N and 100 N. In one embodiment, the force is selected from a list consisting of: 1 N, 5 N, 10 N, 20 N, 30 N, 40 N or 50 N. In one embodiment, the substrate is attached to the cloth using force varying between 1 N and 40 N.

In one embodiment, the diamond suspension is replaced by another abrasive material.

In one embodiment, the dimensions of the elongated shapes are:
height ranging between 5 nm and 10 microns;
width ranging between 10 nm and 10 microns;
length ranging between 10 nm and 1000 microns;
spacing between two adjacent shapes ranging between 10 nm and 10 microns.

In one embodiment, the number of nanowires/nanowalls in the array ranges between 1 and 1,000,000.

In one embodiment, the elongated shapes are parallel to each other. In one embodiment, the elongated shapes are substantially parallel to each other. According to this aspect and in one embodiment, the elongated shapes or portions thereof deviates from 100% being parallel by angles ranging between 0 degrees and 30 degrees. In one embodiment, such deviation from 0 degrees (parallel) occurs only for portions or segments of the elongated shapes. Parallel is referred to the orientation of the long dimension of two or more elongated shapes in one embodiment.

In one embodiment, the formed nanowires/nanowalls are parallel to each other. Deviation from 100% being parallel as discussed above for the elongated shapes is also applicable to the nanowires/nanowalls in some embodiments.

In one embodiment, scratching a substrate to form elongated structure is performed using a rough material that is moved along the substrate. The rough material can comprise sandpaper, diamond structure, or any other rough material strong enough to induce scratching of a substrate. The rough material can be mounted on a roller, and the roller is rolled on the substrate. In one configuration, the roller rotates on a central axis and the substrate is transferred along the surface of the roller. In one embodiment, the rough material is in the form of a brush or a comb, and it is pushed or pulled along the surface of the substrate forming scratches in the substrate. Depending on the structure of the rough material, and the movement direction of the rough material with respect to the substrate or the movement of the substrate with respect to the rough materials, the scratches (elongated shapes) can be formed as straight lines or as curved lines or as lines comprising other shapes (spiral/angled structures/zig zag etc.).

In one embodiment, the elongated shapes are constructed using imprint lithography using an inorganic mold and a SiO₂ substrate. In one embodiment, the SiO₂ substrate is glass, or it comprises glass. In one embodiment, the inorganic mold is alumina. In one embodiment, the alumina is M-plane sapphire. In one embodiment, the M-plane sapphire comprises grooves on its surface. In one embodiment, the grooves on the alumina surface are formed by annealing the M-plane sapphire. In one embodiment, the glass substrate is soda-lime glass.

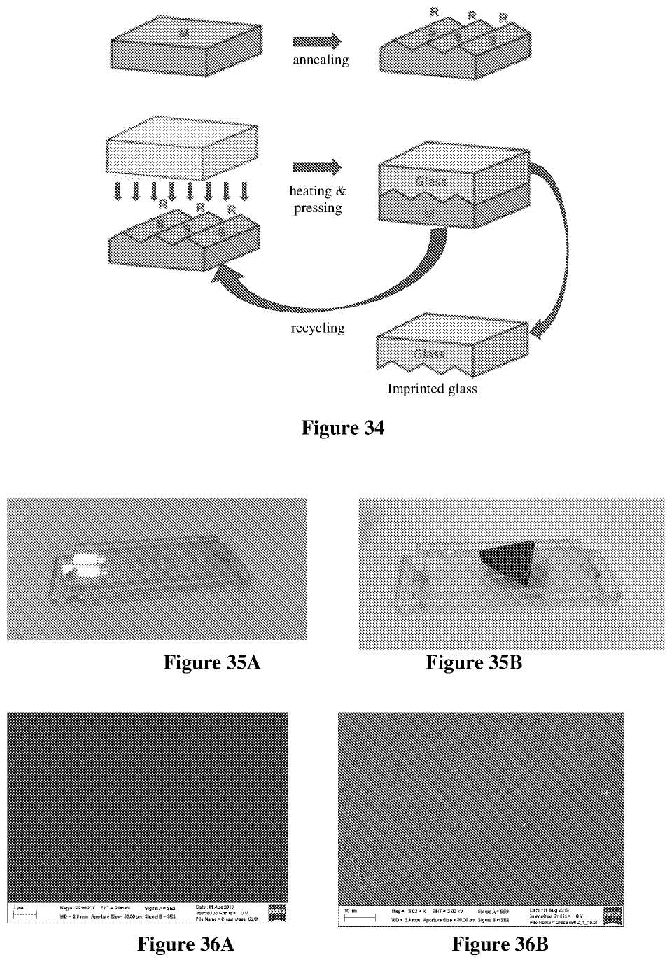

According to this aspect and in one embodiment, the annealed M-plane sapphire comprising grooves on its surface is press against a glass substrate. The two substrates are heated. While heating, the glass fills the grooves of the sapphire, thus acquiring a groove shape that follows the grooves of the sapphire (see FIG. 34). The sapphire is separated from the glass. The glass comprising the grooves is used as a substrate for the growth of nanowires (see FIG. 40A and FIG. 40B). The grooved M=plane sapphire is a robust material and it is used repeatedly as a mold for a very large number of substrates. In one embodiment, such formation of grooved substrates is automated.

### Embodiments of Methods of Producing a Photovoltaic Device

In one embodiment, this invention provides a method of producing a photovoltaic device, said method comprising:
constructing an array of elongated shapes on a substrate;
applying growth-catalyst material on a region of said elongated shapes;
exposing said substrate to a vapor, said vapor comprising:
   atoms/ions required for nanowire/nanowall formation; and
   carrier gas;
thereby forming nanowires/nanowalls adjacent to said elongated shapes;
applying shells on a section of said nanowalls/nanowires, thus forming core-shell nanowires/nanowalls on said section;
applying at least two electrical contacts to said device such that a first contact is applied on and in contact with the shell of a core-shell wire section and a second contact is applied on a non-shelled section of said wire;
   wherein:
said substrate is an amorphous substrate; or
said substrate is a polycrystalline substrate;
the long dimension of said formed nanowires/nanowalls is parallel to the surface of said substrate.

In one embodiment, the step of applying shells comprises:
protecting sections of the wires using a deposited layer;
exposing said wires to a liquid solution comprising at least one atom/ion of the shell material, thereby forming a shell layer on the unprotected wire section(s).

In one embodiment, the contacts are applied using photolithography and metal evaporation. In one embodiment, the contacts are connected to a load, to an electrical measurement device or to a combination thereof.

In one embodiment, an electrical contact area on said substrate/nanowires is defined by photolithography and wherein metal evaporation is conducted into said defined areas. In one embodiment, the electrical contacts comprise Au or Cr/Au. In one embodiment, the thickness of said contacts ranges between 100 nm and 1000 nm. In one embodiment, a portion of said electrical contacts is deposited in a shape of elongated stripes, the long axis of said stripes is deposited perpendicular to the long axis of said nanowires/nanowalls.

In one embodiment, elongated shapes of this invention are straight lines or straight structures. In some embodiments, elongated shapes of this invention are not straight lines. In one embodiment, elongated shapes of this invention are not closed hollow shapes. In one embodiment, the elongated shapes are solid non-hollow shapes. In one embodiment, the NW are grown adjacent to the elongated shapes and at least a portion of the nanowire is exposed to the environment. In one embodiment, a portion of the nanowire cross section at every location along its length is not in contact with the elongated shape. In one embodiment, a portion of the nanowire cross section at every location along its length is exposed to the environment. In one embodiment, the NWs are not enclosed within the elongated shapes. In one embodiment, the NW are not enclosed within hollow elongated shapes. In one embodiment, the NW are not enclosed within closed hollow elongated shapes.

In one embodiment, this invention provides a method of forming core-shell nanowires, the method comprising:
forming nanowires by deposition from a vapor phase;
forming a shell on the nanowires or on portions thereof by deposition from a liquid phase.

In one embodiment, this method is used to form core-shell nanowires for the photovoltaic cells/devices described herein. In one embodiment, the core nanowire comprises CdS and the shell comprises Cu₂S.

In one embodiment, the nanowires do not comprise carbon. In one embodiment, the nanowires comprise only small amounts of carbon as an impurity. According to this aspect and in one embodiment, the NWs comprise less than 5%, or less than 2% or less than 1% or less than 0.5% or less than 0.1% or less than 0.01% or less than 0.001% or less than 0.0001% carbon (units are either w/w, weight in weight or atomic percent). In one embodiment, the nanowires do not comprise carbon nanotubes. In one embodiment, the nanowires do not comprise nanotubes. In one embodiment, the nanowires comprise Si and/or Ge nanowires. In some embodiments, the nanowires do not comprise Si and/or Ge nanowires.

In one embodiment, processes of this invention comprise the step of ‘constructing an array of elongated shapes on a substrate’. It is to be noted that instead of constructing an array of elongated shapes on the substrate, a substrate that already comprises an array of elongated shapes can be provided and used for subsequent process steps. Accordingly in some embodiments, the method step of ‘constructing an array of elongated shapes on the substrate’ can be substituted with ‘providing a substrate comprising an array of elongated shapes’. The provided substrate comprises elongated shapes on it in one embodiment.

In one embodiment, the term “a” or “one” or “an” refers to at least one. In one embodiment the phrase “two or more” may be of any denomination, which will suit a particular purpose. In one embodiment, “about” or “approximately” may comprise a deviance from the indicated term of +1%, or in some embodiments, −1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25%.

### EXAMPLES

### Example 1

### Materials and Methods Guided Nanowires

EBL patterning PMMA 950 A3 (MicroChem) was spin-coated (5000 RPM) on a Si/SiO₂ (300 nm) wafer (Silicon Valley Microelectronics) and baked for 2 min at 180° C. Writing designs patterned with e-Line Plus software using a Raith electron-beam lithography system. Cold developing was done in standard MIBK:IPA at 5° C. for 40 sec.

Pattern transfer after EBL Two pattern transfer processes were employed: 1) wet etch by BOE to form 20 nm isotropic trenches in the SiO₂ layer. And 2) electron-beam evaporation of 10 nm alumina. Last stage in the two pattern-transfer methods is liftoff in acetone.

NIL An imprint resist (PMMA 35K, Resist Ltd) was diluted with anisole (anhydrous, 99.7%, Sigma Aldrich) at different ratios to obtain mixtures that could produce thicknesses ranging from 40-105 nm on 500 μm thick Si samples with a 3000 Å thermal oxide layer (SVM). An ellipsometer (Rudolph Auto EL) and an optical profiler (Zeta-20) were used to measure resist thickness. After spin coating and baking (180° C., 2 min) full wafers were cut into 1.8 cm² squares. All samples were cleaned with a strong flow of N₂. The hard mold was placed face-down on the sample on the chuck of a homemade pneumatic NIL setup. A double layer elastomer sheet was used to seal the sample and mold in place under vacuum. The setup was heated to 200° C., held at high pressure (17 bar N₂) for 5 min and then rapidly cooled to 40° C., after which the sample and mold were separated.

Pattern transfer was accomplished using either the wet etch (T1 configuration) or alumina evaporation (a T2 configuration), as described below. The two methods were used on samples with ˜40 nm and ˜70 nm PMMA thickness, respectively.

Pattern transfer after NIL Two pattern transfer processes were employed: 1) wet etch: an STS ASE ICP (30 mTorr, 30 sccm O₂, no coil, 20 W platen power) was used to etch any remaining resist from the imprinted grooves and was followed by an etch in BOE to form 20 nm isotropic trenches in the SiO₂ layer. 2) alumina evaporation: angle evaporation of hard mask was initially used. Samples were placed 30° from the axis of an e-beam evaporation chamber (PVD, Telemark). A 15 nm Ti cap was evaporated onto the protruding feature edges. An STS ASE ICP (30 mTorr, 30 sccm O₂, no coil, 20 W platen power) was used to etch any remaining resist from the imprinted grooves and was followed by e-beam evaporation of 10 nm amorphous alumina. Last stage in the two pattern-transfer methods is liftoff in acetone.

Mold writing Hard molds were prepared from 325 μm thick Si wafers (SVM) cut into 1.6 cm² squares by etching the native oxide in a buffered oxide etch of hydrofluoric acid (BOE 6:1 with surfactant, J. T. Baker), spin coating the wafers with a 35 nm thickness of 2% HSQ e-beam resist (XR-1451, Dow Corning), writing designs patterned with e-Line Plus software using a Raith electron-beam lithography system with dosage ranging from 1800-3000 pC/cm, and developing the mold in AZ 726 (Clariant GmBH) for 60 s followed by a 30 s water rinse. Plasma ashing (1 min, 1 sccm O₂, 150 W) and thermal annealing (60 min, 600 sccm Ar, 900° C.) hardened developed HSQ into porous silica. To passivate the mold for easy release, a commercial procedure was performed under inert atmosphere (Nanonex NXT-100 protocol).

Catalyst patterning and nanowire growth Photolithography was performed using positive-tone resist NR-9 1000PY (developed with RD-6) and a mask aligner (MA/BA6 Karl Suss) followed by e-beam evaporation (PVD, Telemark) of 5 Å Ni catalyst (for the growth of GaN) or Au (for the growth of all other materials). Dewetting of the catalyst was performed at 550° C. Growth was performed according to published protocols for various materials. Adjustments for growth on Si substrates were made as required.

Structural Characterization Imaging of nanowires were done by scanning electron microscope (Supra 55VP PEG LEO Zeiss). For the characterization of morphology and crystallinity, a focused ion beam (FEI Helios 600 dual beam microscope) was used to cut thin (50-100 nm) lamellae across the nanowires, which were later inspected under a high resolution transmission electron microscope (FEI Tecnai F30). To study the crystallographic orientations, HRTEM images were analyzed using FFT from selected areas, and the FFT peaks were fitted to the crystallographic tables of bulk ZnSe and GaN.

Photoluminescence PL measurements were done using a micro-Raman/micro-PL system (Horiba LabRAM HR Evolution). A 325 nm laser was focused on the nanowire through a reflective objective lens and PL was collected using the same objective and sent to a 300 lines/mm grating and an EMCCD camera.

### Materials and Methods Photovoltaic Cells

Substrate preparation As-received well-cut double-polished M(101̅0) sapphire (Roditi International Corporation Ltd, England) was annealed at 1600° C. for 10 h. The annealing will lead to spontaneous formation of V-shaped nanogrooves on the sapphire surface. In order to have selective-deposited gold catalysts for the growth, the annealed sapphire was firstly marked (either with 5-μm line arrays or 3×30 μm² pads) with a negative photoresist (NR9-1000PY) by a standard UV photolithography, followed by electron-beam deposition of 5-Å-thick gold film. After lift off the photoresist layer with acetone, the gold film was dewetted at 550° C. for 10 min to form gold nanoparticles before being used for growth.

Nanowall growth: the growth of guided CdS nanowires was performed in a home-build two-zone horizontal tube furnace (Lindberg/Blue M 1100° C. Mini-Mite™) with rapid heating ability. Both CdS powder and sapphire substrate were connected with magnets in order to adjust their position by magnet force. In a typical synthesis, CdS powder (0.12 g, 99.99%, Sigma-Aldrich) evaporated at 860° C. served as the precursor and high-purity N₂ was used as the carrier gas. The sapphires with Au catalysts maintained at 560 -600° C. were used for the collection of vapors from the source. The growth usually lasts 20-40 minutes under 300-400 mbar in order to have a micro-scale length. After CdS growth, 25 nm Al₂O₃ layer was deposit over the whole substrate by atomic layer deposition (ALD, Fiji F200) at 250° C. A second photolithography was then performed to define the area to be etched. The etching was performed by dipping the sample into a buffered oxide etch (BOE) solution (6:1 with surfactant, JT Baker) for 28 seconds at room temperature. After removing the photoresist, the selective-etched sample was then used to perform cation exchange reaction in 0.05 M CuCl ammonia solution (25% NH₃) at 50° C. It was then thoroughly rinsed with deionized water, ethanol, and isopropanol (IPA) and blown dry with nitrogen. Last, the rest Al₂O₃ layer was etched by performing another etching in BOE solution for 30 seconds (see FIG. 12).

Structural characterization the morphology of as-grown samples was observed by SEM (Supra 55VP PEG LEO Zeiss). For analyses of the crystallographic structure, orientation, and epitaxial relationships of the nanowalls, a focused ion beam (FIB, FEI Helios 600 Dual Beam microscope) was used to cut thin (50-100 nm) slices across nanowalls, after which they were observed under a high-resolution transmission electron microscope (HRTEM, FEI Tecnai F20).

Nanodevice fabrication a photolithography mask was designed to define an electrode pattern compatible with the catalyst pattern of the guided nanowalls. After growth, sapphires with ordered nanowalls were first marked by standard photolithography. Next, Cr/Au (10/400 nm) metal layers were laid down as electrodes using electron beam deposition (SELENE ODEM) see FIG. 12. After lift-off in acetone, photodetector arrays were obtained. Before electronic and optoelectronic measurements, the device was annealed at 300° for 3 h in a N₂ atmosphere in order to obtain a good contact condition between the nanowalls and metal electrodes.

Electronic and optoelectronic measurements All measurements were done under high vacuum (˜10⁻⁴ Ton) at room temperature using a Janis ST-500 probe system with a Keithley 4200-SCS. A sum simulator (AM 1.5G) was used to illuminate the device and the light intensity was adjusted by metallic neutral density filters (Thorlabs).

### Example 2

### Artificial Epitaxy of Nanowires on Amorphous Substrates

In order to study guided growth by artificial epitaxy of nanowires on amorphous substrates, the first step was the patterning of nanometer-scale straight open trenches on a Si wafer covered with a 300 nm oxide layer. The first attempts were done by EBL. After writing and developing, the trenches were created by either wet-etch of the silica layer using a buffered oxide etch (BOE) or by depositing alumina using electron-beam evaporation. These two methods yield either isotropic, curved trenches or anisotropic trenches with 90° angles between surface and trench walls, respectively (FIG. 2a). More details regarding the fabrication of trenches can be found in example 1. These two different cross-section morphologies of the trenches are referred to as template 1 (T1) and template 2 (T2) respectively (see FIG. 2a). Trench dimensions range from 10-20 nm in height and 80-160 nm in pitch, with various widths. It is noted that the trenches are not designed to confine the horizontal nanowires but only to guide their growth along the artificial features. FIG. 2B shows a scanning electron microscope (SEM) image of straight open trenches created by EBL followed by alumina evaporation and liftoff (T2). Both T1 and T2 trench configuration show similar quality and uniformity and are both used for the growth of horizontal nanowires by artificial epitaxy.

Islands of metal catalyst are patterned using a standard procedure of photolithography, electron-beam evaporation and lift-off. Nanowires of different materials are then grown by chemical vapor deposition (CVD), at similar conditions found for the epitaxial and graphoepitaxial growth of horizontal nanowires on sapphire. In FIG. 2C horizontal ZnSe nanowires are presented, the wires are guided along straight trenches prepared by EBL in a T2 configuration. Nanowire lengths and diameters were comparable to those grown by epitaxy and graphoepitaxy on sapphire, with lengths surpassing 20 μm. The catalyst droplet is apparent at the edge of the nanowires, indicating the expected VLS growth mechanism. Although EBL is a standard procedure for the fabrication of high quality nanoscale-features and is clearly appropriate for the guided growth of horizontal nanowires by artificial epitaxy, it is a low throughput, serial process. Therefore, once successful growth was achieved along open trenches, EBL was replaced by thermal NIL.

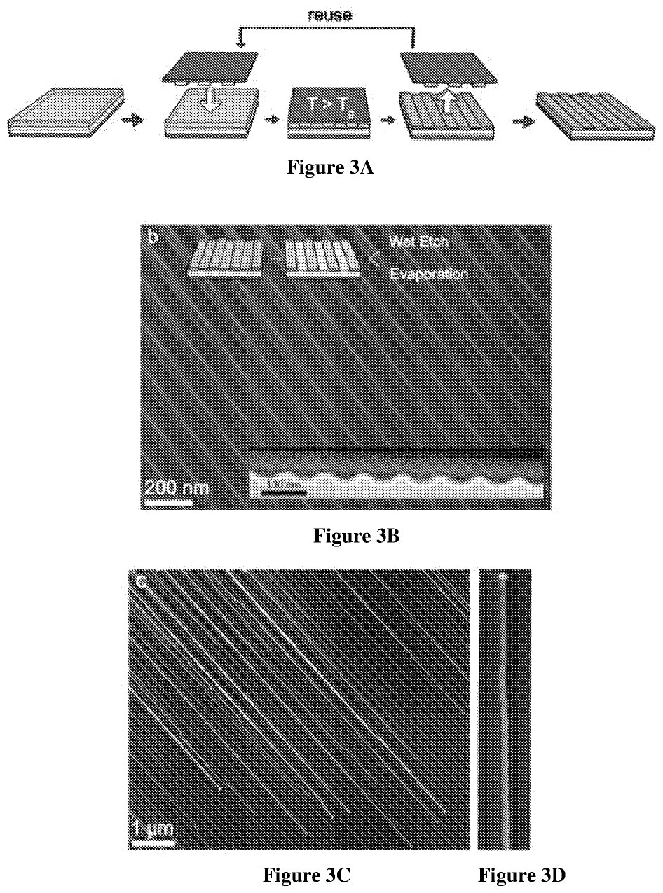

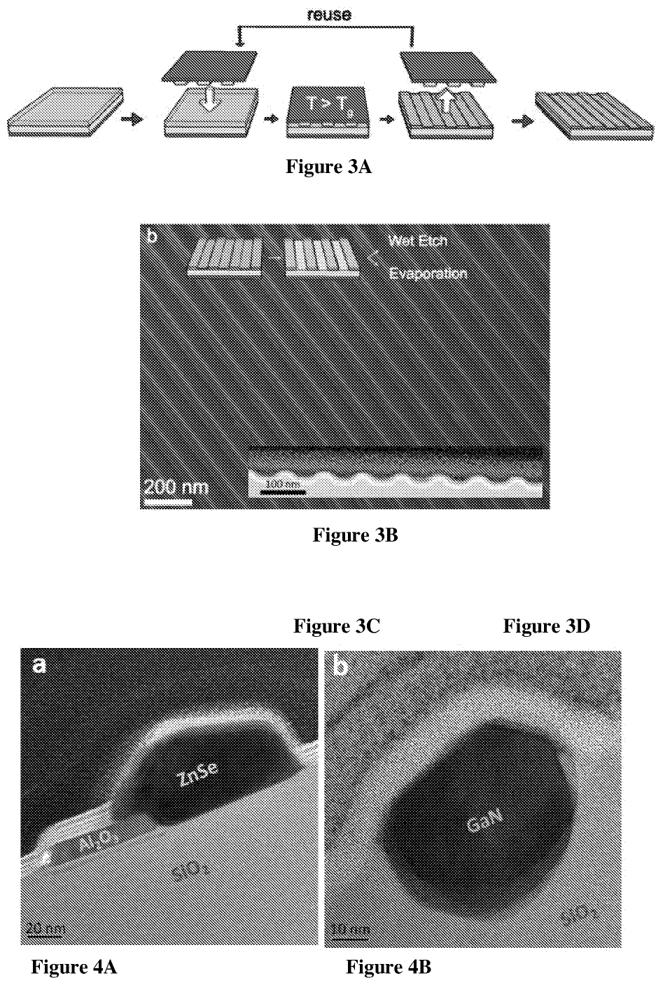

In NIL, the same mold is used to pattern a large number of samples, upgrading guided growth by artificial epitaxy into a parallel process. The mold itself is created by EBL, using hydrogen silsesquioxane (HSQ) as the electron-beam resist. HSQ is used to achieve high resolution features due to its low line-edge roughness and low molecular weight. Upon development and thermal treatment, it hardens into porous silica, and can withstand multiple uses as a hard mold. In thermal NIL, the hard mold is pressed at high pressure into a thermoplastic polymer (the imprint resist) at a temperature in the viscous phase, and then rapidly cooled below the polymer's T_{g} before separation (technical details regarding the imprint process can be found in example 1). Using the same mold to pattern a large number of samples drastically improve the process throughput (FIG. 3A). After molding the pattern into the imprint resist, different methods can be used to transfer the patterned features onto the silica layer. All methods include removal of any polymer remaining in the depressed areas by a gentle reactive ion etching (RIE) as one of the first steps (see example 1). Two pattern-transfer methods were used, based on either wet-etch or deposition of amorphous alumina, in similarity to the final steps in the EBL process. Therefore, the NIL process results in the same two final configurations T1 and T2.

Straight open trenches, with a 120 nm pitch, fabricated by NIL in a T1 configuration, are shown in FIG. 3B. The inset shows a cross section prepared by FIB of similar trenches with an 80 nm pitch. Nanowires of different materials are grown on trenches created both in T1 and T2 configuration. It was found that yield and typical lengths of nanowires are similar in both methods (as detailed herein below). Quality and crystallinity of nanowires grown in the two configurations are discussed below. In FIG. 3C, GaN nanowires grown in trenches prepared by NIL in a T2 configuration, are depicted. As can be seen, the quality of the trenches produced by NIL, realized mainly by their uniformity and low roughness, is no less than those produced by EBL. More importantly, the high quality of the NIL trenches is manifested in the high yield and alignment of nanowires growing along these trenches. As can be seen in FIG. 3D, the nanowire diameter is not determined by the width of the trench, but rather affected by the size of the catalyst droplet, according to the VLS mechanism. The nanowire is attached to one side of the trench, where the alumina wall, only 10 nm in height, guides and aligns the nanowires. This open trench configuration allows a VLS growth with minimal confinement, where the nanowires are at least partially free to expose their most stable facets under the relevant growth conditions. This issue will be further discussed below.

In this study, unlike in previous cases of guided growth, the substrate is amorphous and not single crystal. One important issue arises from the fact that the substrate is amorphous and not a single crystal is the crystallinity of the nanowires. In the past few years it was established that guided horizontal nanowires growing by epitaxy and graphoepitaxy on crystalline substrates not only grow as a single crystal but also show relatively low density of defects. Moreover, their high crystal quality is manifested in their optical and optoelectronic properties. A few works on horizontal nanowires on amorphous substrates demonstrated that the nanowires in this case also grow as single crystals. However, the question of preferred crystallographic orientation of these nanowires remains open. One of the main advantages of the guided growth of nanowires on crystalline substrates is the control over the crystallographic orientation of the nanowires. For example, ZnO nanowires guided on R-plane sapphire grow with extremely high yield in a polar orientation (where the [0001] direction aligns with the long axis of the nanowire). This is due to the strong epitaxial relations between the nanowire and the substrate. Since on amorphous substrates, epitaxial relations are completely absent, it is not clear if the nanowires will exhibit a preferred growth orientation or, with no epitaxy to constrain them, will exhibit a completely random behavior. In addition, an attempt is made to characterize the morphology of nanowires guided by amorphous open trenches, since it can reflect their quality and uniformity. In order to characterize both the morphology and crystallographic orientations of nanowires guided by artificial epitaxy, cross-sectional, electron transparent, lamellae were cut across the nanowires by FIB and observed under a TEM.

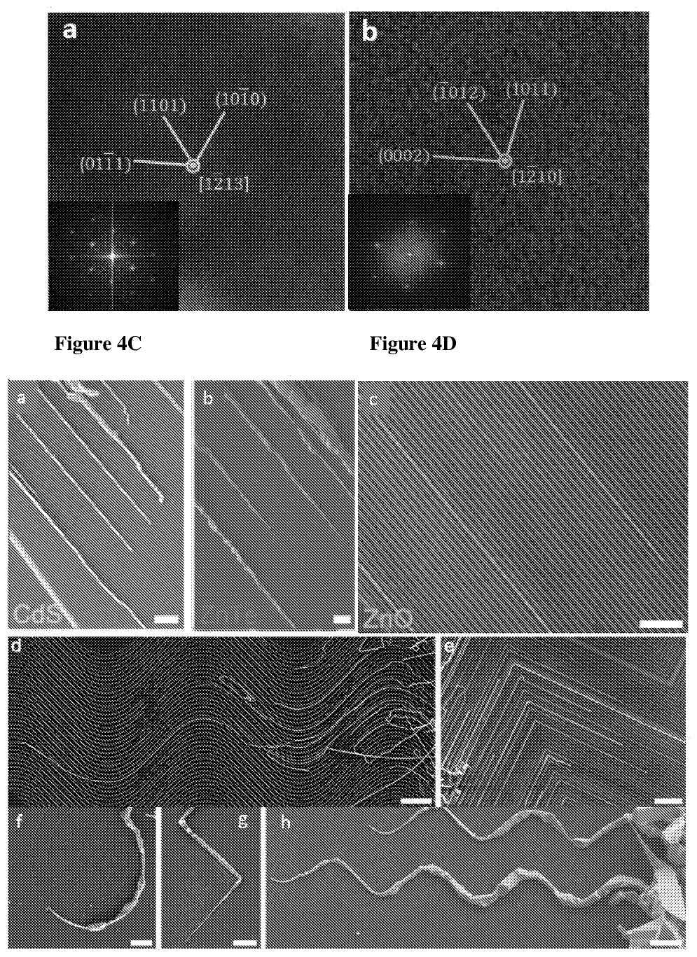

First, the effect of the amorphous templates on the morphology of the horizontal nanowires has been studied. More specifically the structure of nanowires, manifested in their shape, diameter, quality and faceting was investigated. Clearly, a separate consideration is required for T1 and T2 configurations. Low magnification TEM image (FIG. 4A) presents the cross section of ZnSe nanowires guided by artificial epitaxy in a T2 configuration. As can be seen, the ZnSe nanowire grows on the amorphous silica surface and guided by a 10 nm alumina wall. The open trench does not confine the growth and allows the nanowire to accommodate a diameter larger than the dimension of the wall and to display well-defined facets. The wires are observed to grow as high quality single crystals and no structural defects are observed. More examples can be found herein below.

A second lamella was cut across GaN nanowires guided by artificial epitaxy in a T1 configuration. Low magnification image is presented in FIG. 4B. As can be seen, the nanowire cross section appears round at the interface with the substrate and faceted at the upper, exposed part. This cross section resembles GaN nanowires grown horizontally on quartz, in which nanowires grew embedded in the quartz substrate. The silica layer seems to be enveloping the GaN nanowires, distorting the cross section of a typical trench in T1 in comparison to that observed before growth (inset of FIG. 3B). In fact, the reconstruction of the amorphous silica at the conditions of the synthesis has been observed, resulting in a half closed channel around the lower part of the nanowire. In its upper part, which is not in contact with the surface, the nanowire is faceted (more examples are available herein below). Although the nanowires grow as single crystals (see below), a relatively high concentration of plane defects was observed in comparison to GaN nanowires grown by epitaxy and graphoepitaxy modes (see below). It is suggested that the reconstruction of the silica during the growth of the nanowire, leads to a more constrained growth and results in a higher density of plane defects. This observation suggests that the T1 configuration is less preferable for the guided growth of materials with relatively high CVD temperature (950° C. for the guided growth of GaN nanowires).

### Crystallographic Characterization of the Nanowires

In order to characterize the crystallographic orientations of nanowires grown by artificial epitaxy, high-resolution TEM (HRTEM) has been used. Higher-magnification images display clear fringes (FIG. 4C and FIG. 4D, for ZnSe and GaN, respectively) and enable the determination of the crystallographic orientations by using fast Fourier transform (FFT). The FFT peaks are identified with known crystallographic data and fitted to atomic models of ZnSe and GaN. From HRTEM and crystallographic analysis, we find ZnSe nanowires to be high quality single crystals. No evidence for structural defects is observed. This observation is attributed to the growth along open trenches, allowing the crystal to accommodate its stable structure and expose its stable facets under the relevant growth conditions. More interestingly and surprisingly, a well-defined crystallographic orientation has been found. Despite the fact that these nanowires are guided by amorphous features and no epitaxial relations with the substrate play a role in this guiding mechanism, a preferred growth orientation has been found. It was possible to determine the crystallographic orientation of seven nanowires from which five of them grew along the [1̅2̅13] direction in a wurtzite (WZ) structure. This specific direction was not observed on guided ZnSe nanowires on different planes of sapphire.

The same methodology was used for the crystallographic analysis of GaN nanowires. A relatively large variety of crystallographic orientations have been found (see table below). Nevertheless, among the different orientations, [1̅2̅10] has been found to be the most common growth direction. It is noted that even nanowires with the same growth direction can be found rotated in different angles with respect to the growth axis. These observations all resemble the inventor's past findings regarding the guided growth of GaN nanowires on quartz. This similarity is explained by the observed amorphization of the quartz at the interface with the GaN nanowires which in-fact obscures the epitaxial relations, very much like the horizontal growth of nanowires on the amorphous oxide layer of the silicon wafer.

The non-polar orientations: [1̅2̅10] and [1̅1̅00], also known as the a and m directions, respectively, are the most frequently observed crystallographic orientation for GaN nanowires. It was previously demonstrated that the catalyst composition in VLS growth plays a central role in directing the crystallographic orientation of GaN nanowires. More specifically, it was shown that Ni-rich catalyst leads to growth along the a-axis ([1̅2̅10]) on two different substrates. In analogy, Ni is used as the catalyst for the growth of GaN nanowires in this work, which are found to grow most commonly along the a direction. It is suggested that the catalyst composition either stabilizes the (1̅2̅10) planes at the growth front (energetically controlled growth) or changes the barrier between the catalyst and the (1̅2̅10) planes of GaN (kinetically controlled growth). In principle, a third, noncatalytic possible effect can be considered: minute amounts of catalyst can migrate to the sides of the wire and stabilize specific facets, thus dictating the growth direction. Since the nanowires in embodiments of the present invention present a round cross-section at the interface with the silica, and only a small part is faceted, it is considered that the last suggestion is less likely in this case. Based on the absence of epitaxial relations and former observations regarding the preferred growth directions in vertically grown GaN nanowires, the catalyst seems to play a major role in guiding the growth axis of this artificial-epitaxy guided nanowires.

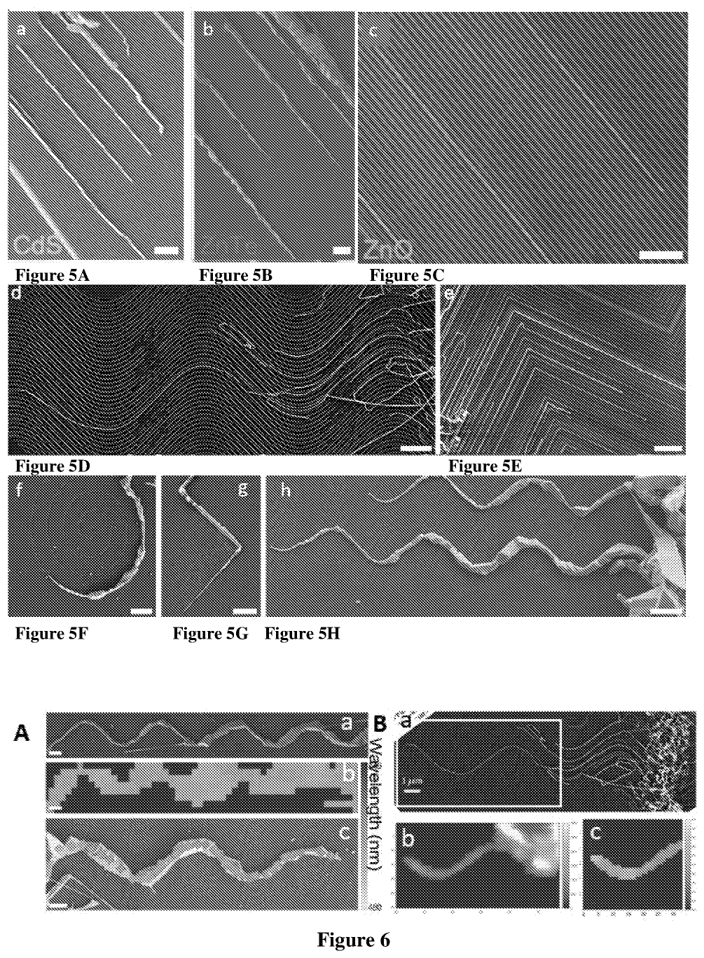

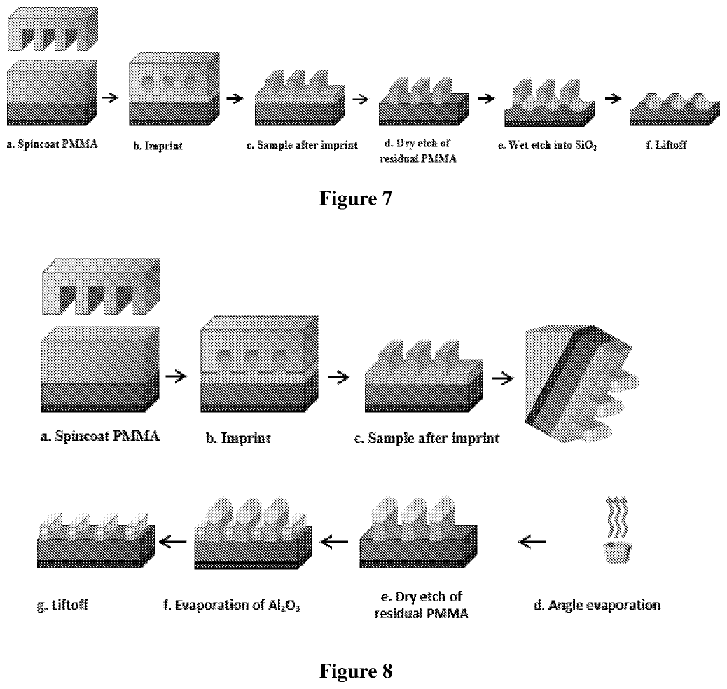

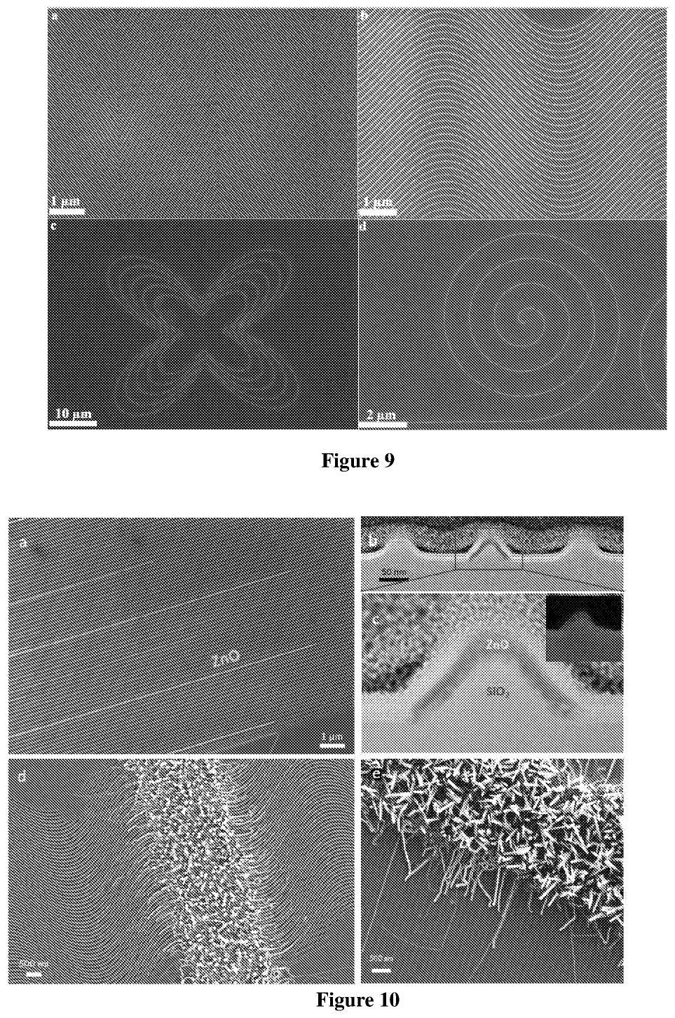

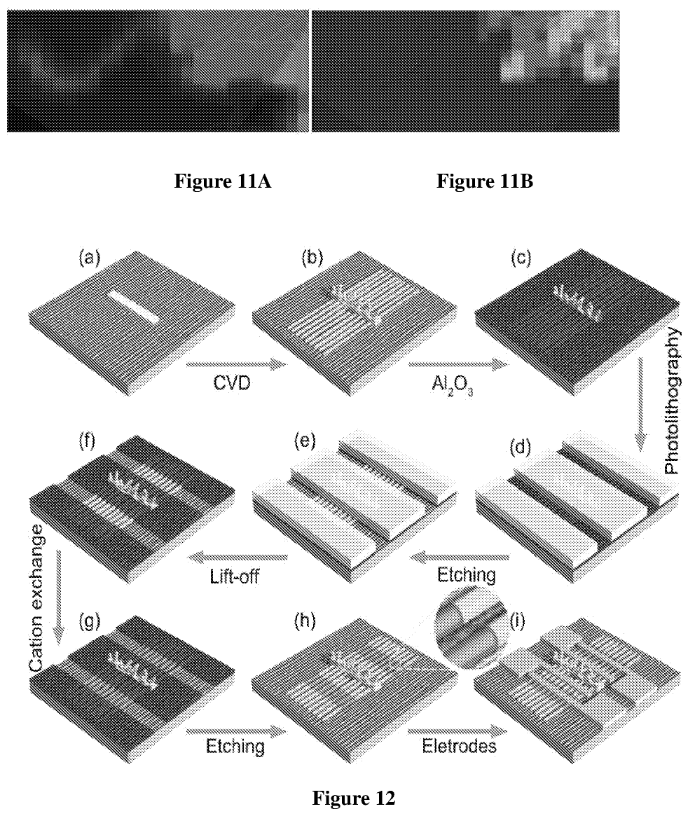

To further test the generality of guided growth by artificial epitaxy in addition to ZnSe and GaN, nanowires of CdS, ZnTe and ZnO have been grown along lithographic open trenches, as depicted in FIGS. 5A, 5B and 5C, respectively. Nanowires from the different materials were grown using either EBL or NIL with both T1 and T2 configurations. As can be seen, all nanowires demonstrate guided growth along the patterned trenches, displaying the adaptability and generality of the method. However, nanowire growth from different materials differs both in yield and nanowire morphology. The observed differences between all five different materials are also observed in the guided growth by epitaxy and graphoepitaxy on sapphire and are discussed below. The CVD process on a patterned silicon substrate is very similar to that on sapphire, and in most cases guided growth by epitaxy, graphoepitaxy and artificial epitaxy can be achieved under the exact same conditions in the same synthesis. In some cases, adjustment of the sample temperature is required to improve the yield of nanowire growth by artificial epitaxy, mainly due to the different thermal conductivity of silicon and sapphire. Guided chalcogenide nanowires often show, in addition to the VLS mechanism that leads to the elongation of the nanowires, a significant extent of vapor-solid (VS) growth, where add atoms are directly absorbed from the gas phase onto the surface of the nanowires. The VS/VLS growth rate can be controlled to some level by adjusting the parameters of the synthesis. A prominent VS growth can be manifested as nanowalls or very “bulky” nanowires, as was observed in guided chalcogenides nanowires on sapphire. The VS growth is present in chalcogenides nanowires growing by artificial epitaxy as well. This phenomenon is most pronounced in the growth of ZnTe in the present working conditions (FIG. 5B). It is noted that even very thick bulky nanowires are well guided by the patterned trenches. The dimensions of the patterned trenches were optimized to the growth of GaN nanowires which do not show any VS growth. More specifically, the pitch of the array, together with the width and height of the trenches were adjusted to fit observed yield and typical diameters of GaN nanowires on sapphire, respectively. The growth yield of chalcogenide nanowires with typically larger dimensions, could be improved by adjusting the spacing, width and height of the trenches.

As for all other materials, the CVD growth of ZnO by artificial epitaxy resolved in elongated nanostructures along the trenches with a droplet at the edge that indicates a VLS growth, as can be seen in FIG. 5C. However, when performing AFM, it was observed that where a nanowire seemed to grow from the SEM top view, the trench wall was higher in a few nanometers. To better understand the structure, a thin electron-transparent lamella was cut using FIB and examined by TEM. It was found that instead of ZnO nanowires, a thin layer of ZnO was covering the wall of the trench, creating some sort of cupping (see FIG. 10). By adjusting the synthesis parameters, the growth of ZnO nanowires inside the trenches was successful, but the nanowires were short (˜1 micron). Although the yield and alignment of ZnO nanowires on sapphire guided by epitaxy is extremely high, it seems that the guidance by graphoepitaxy is usually more challenging. Since guided growth by artificial epitaxy, is only topographic, it is expected to be less appropriate for the guidance of long ZnO nanowires.

Growing nanowires on patterned amorphous substrates opens up the opportunity to grow them in arbitrary shapes and expand the guided growth approach beyond the realization of straight nanowires. To test the possibility of growing arbitrarily shaped nanowires, zigzag, sinusoidal and spiral features were patterned by NIL in both T1 and T2 configurations. The growth of GaN and ZnSe, within the arbitrarily shaped trenches is presented in FIGS. 5D and 5E. As shown in FIG. 5D, GaN nanowires follow the sine wave shaped trenches in a T1 configuration. The nanowires do not show any VS growth, and the diameter stays constant along the wire. In a few cases the nanowires manage to ‘jump’ between adjacent trenches, indicating the need of higher walls. While the height of the walls proved to be fit for the growth of aligned straight nanowires, it seems that the trenches are a bit too shallow for the growth of non-straight nanowires.

Zig-Zag-shaped GaN nanowires grown in a T2 configuration are presented in FIG. 5E. The nanowires nicely follow the sharp turns of the 90° turns with yield that is comparable to that of straight nanowires guided by artificial epitaxy. More examples are available herein below. In general, the GaN nanowires seem to better follow the shaped trenches in a T2 configuration in comparison to T1. This is the case even when the nanowires are forced to take sharper turns during growth. It is suggested that the sharper profile of the T2 trench is preferred for the growth of nanowires in arbitrary shapes, which grow attached to the trench's wall. GaN nanowires growing in the curved smooth profile of the trenches in the T1 configuration are more prone to escape from them. FIGS. 5F, 5G and 5H, show the growth of ZnSe along a spiral, zigzag and a sinewave shapes, respectively. The shaped nanowires all show a high level of tapering due to pronounced VS growth. According to the VLS mechanism, the tip of the nanowire, close to the catalyst droplet, is the most recently crystallized segment. This segment is in the same dimensions of the patterned trenches. During the synthesis, material from the vapor phase nucleates on top of the nanowire, leading to a thicker and bulkier morphology towards its other end. This logic suggests that the nanowire follows the shaped groove while it is still in the appropriate dimensions and VS growth occurs on top of the shaped wire. Although VS growth is sometimes apparent in epitaxial and graphoepitaxial guided ZnSe nanowires, it is much more pronounced in the shaped nanowires. It is suggested that the growth in a curved or kinked configuration, induces a higher density of defects in and on the surface of the nanowires, and thus results in more nucleation sites for VS growth. This is significant for the growth of shaped chalcogenide nanowires which tend to suffer from VS growth, as manifested by thicker and chunkier morphology.

After growing sine-wave shaped GaN (FIG. 5D) and ZnSe (FIG. 5H) nanowires, their optical characterization has been conducted in comparison to nanowires under post growth curving. As mentioned above, wavy configurations of nanowires can be achieved also in post-growth methods by transferring vertically grown nanowires onto a pre-strained elastomer and releasing the tensile strain. This approach results in a periodic modulation in the PL energy, where the buckled segments show a red-shifted PL emission with respect to the straight segments. This effect is attributed to a strain-induced band-gap shrinking. In general, bent nanowires (and other nanostructures) show a red-shift in their PL and CL emission. However, the nanowires in this work were not bent after growth but rather formed along a curved feature. The influence of such growing mode on their optical properties, and especially on their NBE emission in this case is not clear. In order to characterize the sinewave shaped GaN and ZnSe nanowires guided by artificial epitaxy, the PL emission along the curved nanowire has been mapped. He-Cd laser with a 325 nm wave-length was used for excitation. Mapping is done by scanning a predetermined area with a piezo stage where at each position a spectrum was acquired.

FIGS. 6Aa and 6Ab are SEM images and the complementary hyperspectral map of a sinewave ZnSe nanowire guided by artificial epitaxy, respectively. Significant VS growth is observed, typical to the shaped chalcogenide nanowires, as mentioned above. The hyperspectral map is created by fitting a Gaussian to the NBE peak of ZnSe and presenting the extracted wavelength according to a color-scale. Variation of 8 nm in the band edge emission is observed at the range of 495.5-497.5 nm, where the maximum error of the fitting is 0.6 nm. However, no correlation between the NBE energy and the periodic shape of the nanowire is found. The relatively wide range of NBE energies is attributed to the significant VS growth. CL has been performed on an additional sinewave shaped ZnSe nanowire. FIG. 6c shows the CL NBE peak position on top of the SEM image. Here too a variation in the NBE energy from different points along the nanowire is observed, but with no correlation to the periodic curved geometry of the nanowire.

Unlike the sine-waved ZnSe nanowires, sine-waved GaN nanowires exhibit no VS growth, as presented in FIG. 6Ba. FIG. 6Bb shows the complementary PL intensity map of the NBE emission of the marked area. In order to exclude signal from adjacent nanowires, focus was on the half sine wave at the far edge of the nanowire and the hyperspectral map was plotted (FIG. 6Bc). A clear red-shift of the NBE emission is observed with correlation to the curved geometry of the nanowire. Curved region differs from the straight region by 4 nm (358 nm and 362 nm) where the maximum error of the Gaussian fit is 0.2 nm. This red shift indicates strain-induced band gap reduction, as found in post growth bent nanowires. Nevertheless, it is noted that no yellow luminescence, which is correlated with defects in GaN, is observed neither in straight nor in curved regions.

To summarize this example, artificial epitaxy was used to guide five different materials along straight and arbitrarily shaped open trenches. Using the high throughput process of NIL, nano lithographic trenches were fabricated with comparable yield and quality of those fabricated by EBL. Two different trench configurations were examined and were found to be useful for the guided growth of nanowires by artificial epitaxy. Although the substrate is amorphous, straight nanowires were found to grow along preferred crystallographic orientations. It is suggested that the catalyst plays an important role in promoting specific orientations at the absence of any epitaxial relations between the nanowire and the substrate. Guided growth by artificial epitaxy was found to be general and adaptable to the growth of different materials and in principle can be used for the growth of any other material. The precise dimensions of the trenches as well as the growth parameters can be optimized for each material to improve the yield and morphology of the nanowires. Photoluminescence and cathodoluminescence were used as a noninvasive tool to characterize sinewave shaped nanowires. In the absence of VS growth, a red-shift in the NBE emission was observed in higher curvature segments of a GaN nanowire, suggesting a strain-related band gap decrease, as in the case of post growth bending of nanowires. This combination of top down and bottom up approach expands the guided growth approach beyond the growth of straight nanowires on crystalline substrates. Nanowires from different materials can grow in pre-designed shapes with control over their location, for the fabrication of specialized devices on different substrates.

### Example 3

### Photovoltaic Devices Comprising Core-Shell Nanowalls

Annealed M(101̅0) sapphire with spontaneously-formed periodic V-shaped nanogrooves was selected as the collection substrate for the site-controlled aligned CdS nanowalls. Typical experimental steps are schematically shown in FIG. 12. First, arrays of gold pad (5 Å in thickness) were selectively deposited onto the sapphire surfaces by a combination of standard photolithography and electron-beam deposition, which defines the start locations of subsequent nanowires. The next step was the growth of self-aligned CdS nanowalls from these site-controlled pads by a combination of conventional thermal evaporation process and the graphoepitaxy effect of the substrate. The guided CdS nanowalls was then entirely masked with a 25-nm-thick polycrystalline Al₂O₃ layer via atomic layer deposition (ALD), followed in turn by defining the region to be etched via photolithography, etching in 1:6 buffered oxide etch (BOE) solvent for 28 s, and lift off photoresist (NR9-1000PY) in acetone. After dipping the sample into a 0.05 M CuCl ammonia solution (25% NH₃) for 2-5 s at 50° C., the exposed CdS region defined by the photolithography was converted to n-CdS@p-Cu₂S core-shell structure via a cation exchange reaction. Thereafter, remained Al₂O₃ mask was removed by a second BOE etching before predictable deposition of metal electrodes onto the core-only and core-shell segments.

This route offers at least four advantages compared with the existing methods with respect to fabrication of anticipated core-shell nanowire horizontal arrays for monolithic integration of photovoltaic cell. First and foremost, the vapor-phase surface-guided horizontal growth combined the nanowall synthesis and alignment into one step, thus provides a cost-effective and easy to scale-up method for direct preparation of highly ordered nanowire horizontal arrays from the bottom-up. Second, the solution-processed cation exchange reaction enables a formation of high-quality epitaxial heterointerfaces without high-temperature doping and deposition processes. Third, the nanowall sites were pre-determined by the location of the catalyst that can be defined by the photolithography process prior to the nanowall growth. Last but not least, the shell lengths and sites are pre-defined as well by the photolithography process prior to the shell formation, instead of after the shell formation as described in the literature. As a result of these advantages, photovoltaic cell can be constructed in a scalable manner simply by using a photolithography mask of electrode that is compatible with the catalyst pattern of the guided nanowalls, without additional postgrowth transfer and alignment steps. More importantly, miniaturized photovoltaic tandem modules can be constructed from these site-controlled horizontal arrays. Consequently, this provides additive output voltage at a microscale regime, which has rarely been investigated with the conventional thin-film cells and the cells made of vertical nanowire arrays. Further, it should be mentioned that more cells can be packed into a small volume simply by replacing photolithography with electron beam lithography, which has a higher spatial resolution. Lastly, the elimination of postgrowth selective shell-etching is critical for achieving high photovoltaic performance based on core-shell nanowires because: i) it seems to be a tricky task to control the etching thickness of shells after the shell formation; ii) the postgrowth shell etching may introduce contamination and damage onto the nanowire core, leading to degradation of photovoltaic performance.

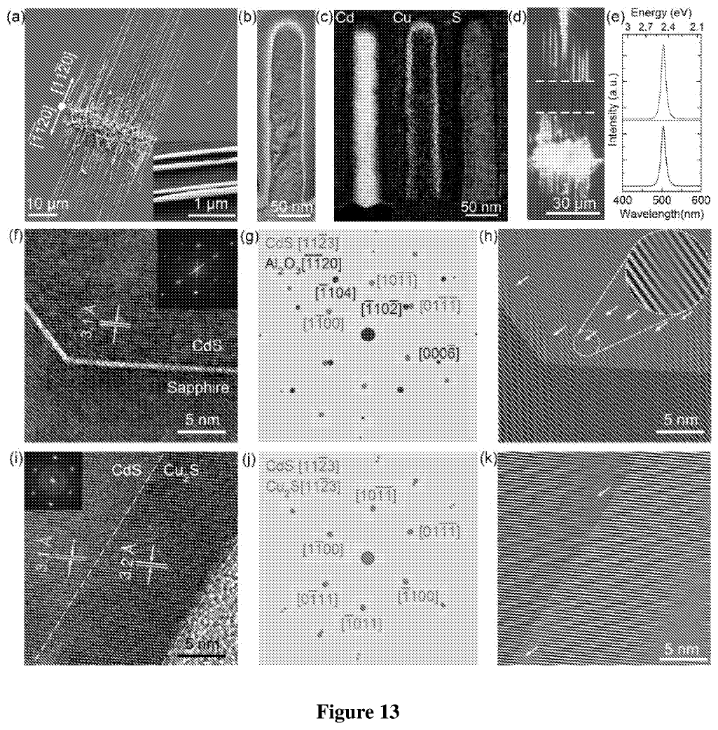

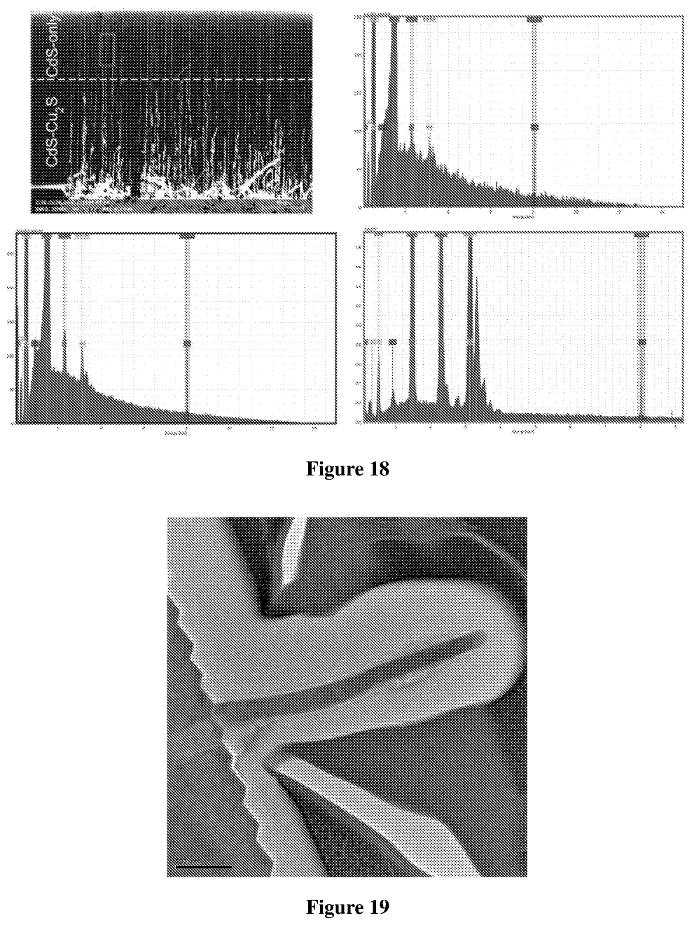

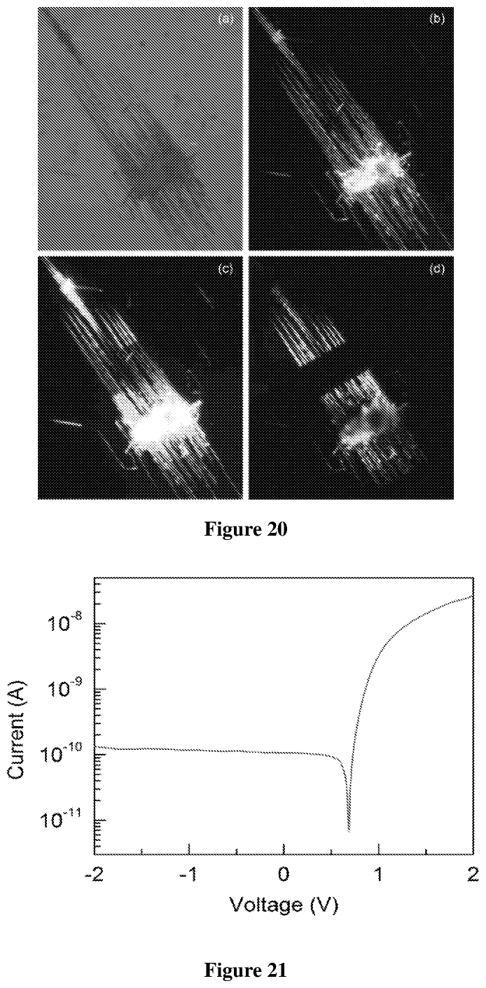

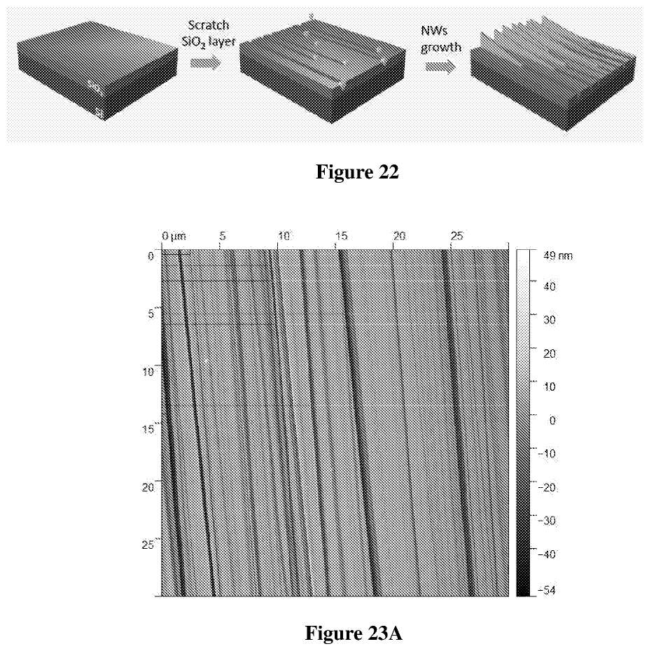

FIG. 13a shows the scanning electron microscopy (SEM) image of the sample after a 30-minute CdS growth. Horizontally ordered CdS nanowires with micrometer-scale length and nanowall geometry (inset) were self-aligned along the periodic V-shaped nanogrooves with ±[112̅0]_{Al}_{₂}_{O}_{₃} directions (FIG. 17). As expected, the sites of these nanowalls are successfully controlled by the position of the catalyst pad (see the dashed rectangle in FIG. 13a). The morphology of these nanowalls is well kept after the solution-processed selective-area cation exchange reaction (FIG. 17). Anyhow, Cu was detected at the photolithography-defined region that had undergone the cation exchange reaction (FIG. 18), indicating the transformation of CdS to Cu₂S after the reaction. A focused ion beam was then used to cut thin slices across the Cu-containing segments, after which they were investigated with transmission electron microscope (TEM). Cross-sectional TEM image (FIG. 13b) shows that the angle of the V-shaped nanogrooves is around 128°, closing to the angle predicted by the atomic model, hence the slopes of the nanogroove are composed of R{101̅2} and S{101̅1} lattice planes. All 10 nanowires that were checked by TEM have a well-defined nanowall geometry, with heights of 130-490 nm, widths of 20-50 nm and height-to-width ratio up to 14 (FIG. 19). Two-dimensional (2D) electron energy loss spectrum (EELS) mapping revealed that S was uniformly distributed throughout the nanowall cross section, whereas Cd was detected at the core region and Cu stayed near the nanowall surfaces (FIG. 13c). The 2D EELS mapping results suggest that the photolithography-defined segment of each nanowall is composed of CdS core and uniform Cu₂S shell, forming a core-shell heterostructure. Under illumination of 405-nm laser light, no visible emission was observed from the CdS@Cu₂S core-shell region, while a bright green emission was observed from the CdS-only region, as shown in FIG. 13d and FIG. 20. The photoluminescent (PL) spectrum acquired from the segment with bright green emission (cyan, FIG. 13e) displays a clean narrow peak with peak wavelength of 504 nm (2.46 eV) and width of ˜15 nm, the same as the PL spectrum collected before conducting the cation exchange reaction (purple, FIG. 13e), therein it originates from the band edge transition of CdS. The absence of defect-related emission expected at the lower energy (longer wavelength) side indicates that these CdS nanowalls possess a high single-crystal quality and the cation exchange reaction introduces negligible defect states into the nanowalls.

Cross-sectional TEM images of the CdS-sapphire and Cu₂S@CdS interfaces (FIG. 13F and FIG. 13I, respectively) and their corresponding fast Fourier transformation (FFT) patterns (inset in each panel) suggest that both the sapphire substrate and nanowalls possess a single-crystalline quality after the growth. Unlike the abrupt V-shaped CdS-sapphire interface (FIG. 13F), the CdS@Cu₂S interface is atomically continuous (FIG. 13I), indicating the high-quality of these epitaxial hetero-interfaces, which plays a key role for the high-performance to be pursued. In order to identify the crystal structure and crystallographic orientation of the nanowalls, their FFT patterns were simulated with the known crystallographic data and atomic models, as shown in FIGS. 13g and 13j, respectively. FIG. 13g reveals that CdS nanowalls have a hexagonal crystal structure with a [112̅3]_{CdS}∥[112̅0]_{Al}_{₂}_{O}_{₃} growth axis. The transversal and top lattice planes of these nanowalls are identified to be {11̅00} and {101̅1̅} lattice planes, respectively. Since the surface energy of top {101̅1̅} surfaces is higher than that of lateral {11̅00} surfaces, surface-adsorbed atoms from the CdS vapor during the high-temperature growth would diffuse preferentially to the more chemically active {101̅1̅} surfaces, leading to a faster CdS growth along the top surface than that along the left- and right-sides, and eventually the formation of well-defined nanowall geometry. FIG. 13j suggests that the Cu₂S-FFT pattern is almost overlapped with the CdS-FFT pattern, indicating that the Cu₂S has the same hexagonal crystal structure as CdS and their crystal lattice alignment is matched well with each other. In FIG. 13h, the selected inverse-FFT image shows that many misfit dislocations exist at the CdS-sapphire interfaces, which is reasonable considering that CdS and sapphire are different crystal structures and the lattice mismatch along [112̅0]_{CdS}∥[0006̅]_{Al}_{₂}_{O}_{₃} directions is up to −4.5%. In contrast, only a few misfit dislocations were identified across the CdS@Cu₂S interface (FIG. 13k) because the CdS and Cu₂S in these nanowalls are the same hexagonal crystals with a small lattice mismatch, and their crystal lattice alignment is matched with each other (FIG. 13j). The achieved high-quality epitaxial hetero-interfaces with few misfit dislocations is critical to reduce interface states and carriers-trapping centers, consequently improving the performance of the resultant photovoltaic cells.

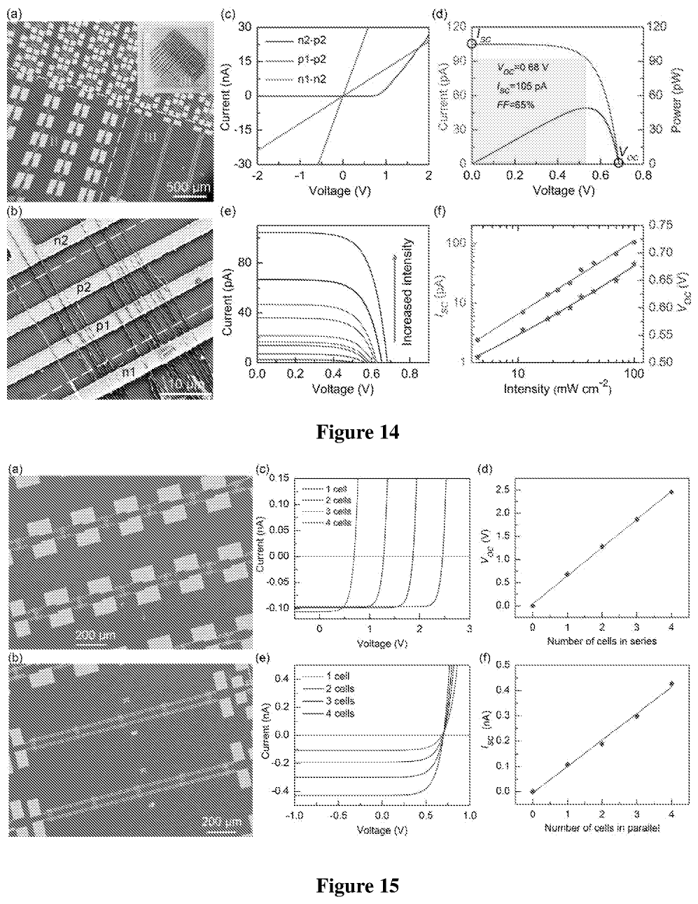

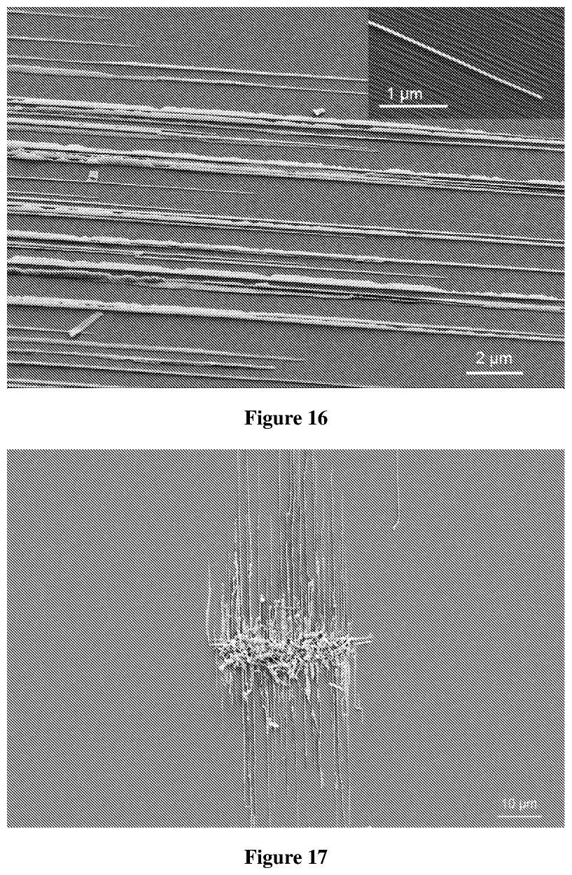

The above characterizations confirmed that self-aligned n-CdS@p-Cu₂S core-shell nanowalls with controlled sites, micro-scale lengths, high-quality epitaxial heterointerfaces were prepared on the insulating sapphire surfaces. The length (20 μm) and site (˜20 μm away from the catalyst pad) of the Cu₂S-shells were pre-defined by the photolithography process before their formation. Consequently, electrode contact can be laid down predictably and selectively onto the cores and shells without postgrowth selective shell-etching, which enables an easy to scale-up, straightforward implementation of microscale photovoltaic cells (FIG. 14A). FIG. 14B shows the SEM image of a representative photovoltaic cell, in which two metal electrodes were deposited deterministically onto the CdS-only and CdS@Cu₂S core-shell region, respectively. The linear I-V curves recorded from the core-core (n1-n2) and shell-shell (p1-p2) configurations indicate that the metal electrodes possess an ohmic contact with the core and shell segments of the nanowalls, respectively (FIG. 14c). In contrast, the I-V curve collected from the core-shell configuration (n2-p2) exhibit a well-defined rectifying behavior with on-off current ratio in the order of 10² (FIG. 21), demonstrating that the CdS@Cu₂S core-shell heterojunctions behave as well-defined p-n diodes (FIG. 14c). Such a result is expected because intrinsic CdS and Cu₂S were recognized as n-type and p-type semiconductors due to background impurities/defects, respectively.

FIG. 14d shows that the photovoltaic cell made of 9 parallel nanowalls (n2-p2) has a large open-circuit voltage (V_{oc}) of up to 0.68 V, and fill factor (FF) of 65%. The open-circuit voltage is a new record for CdS-Cu₂S photovoltaic cells (the maximum reported V_{oc} is 0.61 V), and the FF value is close to the theoretical limit of thin-film CdS-Cu₂S photovoltaic cells (71%). These two parameters are fundamentally related to the junction quality and carrier collection efficiency, thus the high values indicate the high quality of the CdS-Cu₂S heterojunction and the enhanced carrier collection efficiency of the core-shell structure. FIG. 14e shows that the short-circuit photocurrent (I_{sc}) decreased from 105 pA to 2.5 pA while V_{oc} reduced to 0.51 V from 0.68 V with the decrease of incident light intensity. Plots of I_{sc} and V_{oc} as a function of light intensity (FIG. 14f) show that I_{sc} and V_{oc} have a linear and logarithmical dependency on the incident light intensity, respectively. The drop of V_{oc} with decreasing light intensity (ΔV_{oc}/Δln(I)) is about 36 mV, close to the value of thin-film CdS-Cu₂S photovoltaic cells (39 mV), and much smaller than that of silicon-nanowire solar cells (56 mV). The small value of ΔV_{oc}/Δln(I) implies smaller performance degradation of these cells under low light intensity, which suggests their great potential for indoor application with lower illumination level (10-100 μW/cm²).

The energy conversion efficiency (η) of these cells was estimated by η=I_{sc}V_{oc}FF/PS, where P is the power density of sun simulator (1 kW·m⁻² for 1 sun intensity), S is the effective area for light absorption and is estimated as S=w/n in terms of the nanowall width (w), the shell length outside electrode covered (l=12 μm) and number of nanowires (n, counted by SEM). On the basis of TEM observation, the nanowall width is in the range of 20-50 nm, therefore the lower and upper limit of η for this cell is 0.8% and 2.2%, respectively, under 1 sun illumination. Summary of 10 cells yields V_{oc}=0.49-0.70 V, I_{sc}=8.1-17.2 pA/nanowall, FF=50%-67%, and the upper limit of conversion efficiency n=1.1-2.5%.

TABLE 1
Performance summary of 10 photovoltaic cells

| No. of | I_{sc} | I_{sc}/Nanowall | J_{sc} | V_{oc} | FF | η |
|---|---|---|---|---|---|---|
| Nanowalls | (pA) ^{a)} | (pA) ^{b)} | (mA/cm²) | (V) | (%) | (%) ^{c)} |
| 11 | 97 | 8.8 | 0.37 | 0.70 | 59 | 1.5 |
| 5 | 86 | 17.2 | 0.72 | 0.58 | 62 | 2.5 |
| 9 | 73 | 8.1 | 0.34 | 0.68 | 50 | 1.1 |
| 6 | 52 | 8.7 | 0.36 | 0.66 | 64 | 1.5 |
| 12 | 132 | 11.0 | 0.46 | 0.68 | 63 | 1.9 |
| 16 | 181 | 11.3 | 0.47 | 0.51 | 63 | 1.5 |
| 10 | 85 | 8.5 | 0.35 | 0.55 | 62 | 1.2 |
| 9 | 105 | 11.7 | 0.49 | 0.68 | 65 | 2.2 |
| 13 | 131 | 10.1 | 0.42 | 0.49 | 60 | 1.2 |
| 7 | 63 | 9.0 | 0.37 | 0.63 | 67 | 1.6 |
| Average | 100 | 10.4 | 0.43 | 0.62 | 62 | 1.6 |

Note:
^{a)} measured short-circuit current from individual cell made of a few parallel nanowalls.
^{b)} calculated short-circuit current divided by number of nanowalls, we assumed all nanowalls have the same sizes.
^{c)} calculated upper limit of η, where the nanowall thickness is estimated to 20 nm for the calculation.

The energy conversion efficiency of these cells is lower than the reported values from cells made of similar structures. Considering that the open-circuit voltage and fill factor values approach the records of equivalent thin-film cells and the cells made from similar CdS@Cu₂S core-shell nanostructures (Table 2), the main reason of this low efficiency is attributed to the low short-circuit current.

TABLE 2
Performance of CdS-Cu₂S photovoltaic cells based
on different structures.

| | V_{oc} | I_{sc} | FF | η | |
|---|---|---|---|---|---|
| Structure | (V) | (mA · cm⁻²) | (%) | (%) | |
| Thin films | 0.54 | — | 71 | — | Previous |
| Single core- | 0.61 | 11.4 | 80.8 | 5.4 | \| |
| shell nanowire | | | | | |
| Vertical core- | 0.45 | 12.5 | 68.1 | 3.8 | \| |
| shell nanorods | | | | | |
| Singe core-shell | 0.54 | 3.47 nA | — | 0.7 | \| |
| nanowire under | | | | | |
| compressive strain | | | | | |
| Single topotaxial | 0.32 | 5.5 | 39.7 | — | \| |
| nanowire | | | | | |
| This work | 0.49-0.70 | 8.1-17.2 pA ^{a)} | 50-67 | 1.1-2.5 ^{b)} | This |
| | | | | | work |

Note:
V_{oc} and I_{sc} are the open-circuit voltage and short-circuit current under 1 sun illumination, respectively. FF and η is the fill factor and energy-conversion efficiency under 1 sun illumination, respectively.
^{a)} measured I_{sc}, divided by the number of nanowalls; all nanowalls were estimated to be the same sizes.
^{b)} calculated upper limit of η, where the nanowall thickness is estimated to 20 nm for the calculation.

The low short-circuit current originated from the insufficient light absorption in the Cu₂S shells. On one hand, the shell thickness (<20 nm) is too small to enable an efficient light absorption. On the other hand, these nanowalls have a large height-to-width ratio and they are standing with their narrow facets on the sapphire surfaces, therein only their narrower top facets act as effective absorption area since the incident light is perpendicular to the sapphire surface, which reduces the light absorption significantly. In view of these factors, guided nanowires with optimized thickness and height-to-width ratio are desirable for the enhancement of light absorption, and thus energy conversion efficiency of such cells in the future. Even though the conversion efficiency calls for further improvement, these microscopic photovoltaic cells will most likely be useful in niche applications where their small size is key, such as nanoelectronics, miniaturized low-power autonomous wireless electronics, tiny sensors or robots whose sensors and electronics might benefit from an integrated power source. Nevertheless, core-shell nanowalls exhibit some potential benefits. First of all, the core-shell geometry delivers simultaneously a long length scale for light absorption and a short length scale for minority carrier diffusion, leading to a promising improved charge injection and separation efficiency, and accordingly high energy-conversion efficiency of photovoltaic cells. Second, the nanowall geometry, similar to the reported vertical nanowire arrays, is expected to offer lower optical reflectivity, higher light trapping, and less material consumption than equivalent planar configuration. Third, the nanowall geometry enables also a more efficient relaxation of lattice-mismatch strain than epitaxial thin-films, therefore less defects in the CdS@Cu₂S hetero-interfaces.

In addition to the advantage of straightforward implementation of photovoltaic cells in large numbers, the other important virtue of these core-shell nanostructures is the facile monolithic integration into microscopic photovoltaic modules, especially the tandem modules for multiple output voltages. A subsequent connection between the CdS-core electrode of one cell and the Cu₂S-shell electrode of adjacent cell enables the monolithic integration of tandem cell modules (FIG. 15a). The core-core and shell-shell connection between different cells, in contrast, enables the construction of in parallel cell modules (FIG. 15b). FIG. 15c-f shows that the best operation achieved for each configuration with up to 4 cell components. For the tandem modules, the open-circuit voltage is additive as a function of the number of series-connected cells in the presence of matched short-circuit currents and fill factors (FIG. 15c). FIG. 15d further confirms that the open-circuit voltage exhibits a linear increase when the cell numbers less than 4, and an open-circuit voltage up to 2.5 V was successfully obtained from the cell module made of 4 series-connected cell elements. Such a large open-circuit voltage provides a sufficient potential for self-driven solar water splitting, where photovoltage over 1.6 V is required, taking into account the over-potential losses. In comparison, the cell modules in parallel show additive short-circuit currents without notable changes in their open-circuit voltages and fill factors (FIG. 15e). FIG. 15f further shows that the short-circuit current is scaled linearly with the number of cells connected in parallel. Therefore, both the V_{oc} and I_{sc} are additive as a function of the connected cell numbers without a notable decrease in the fill factor for each case, demonstrating the reproducibility and versatility of these nanowall-based photovoltaic cells. When individual photovoltaic cells are connected for higher output power, it is essential that the cells in parallel have matching voltages and the tandem cells have matching currents to maximize the performance of the cell modules. It is worth emphasizing again that while a great number of nanowire-based photovoltaic cells have been reported so far, their capability of monolithic integration into miniaturized cell modules desired for autonomous wireless microsystem has been rarely investigated because of the major challenge in producing site-controlled core-shell nanowire horizontal arrays required for the integration. In this regard, the successful demonstration of cell modules in the present invention, especially the microscopic photovoltaic tandem modules, represents a methodology and nanotechnology advance in monolithic integration of nanowire-based photovoltaic modules.

### Example 4

### Guided Nanowires Grown on Scratched Surfaces

Guided nanowires were grown on scratch surfaces according to the following procedure:

cloth was attached to the ‘wheel’ of a polishing machine (LaboPol-2 with LaboForce-3 head). The cloth was soaked with water. The cloth was sprayed with a water-based diamond suspension, and the suspension was dispersed with water at 250 rpm.

The wafer to be scratched was attached to a spring at the edge of the cloth and the force was adjusted. The wafer was polished at 250 rpm for 10-20 sec. Following polish, the wafer was sonicated for 5 minutes in consecutive baths of: acetone, IPA and H₂O in order to dispose of diamond suspension. Sample size was 5 mm×10 mm.

Characterization of surfaces scratched at different forces was conducted using AFM. Results are summarized in table 3:

TABLE 3
Surface scratch parameters for various applied forces

| Force* | ~10 N | ~20 N | ~30 N | ~40 N |
|---|---|---|---|---|
| Deepest scratch [nm]** | 22 | 28 | 44 | 55 |
| Shallowest scratch [nm] | 1.1 | 1.0 | 1.0 | 1.0 |
| Average depth [nm] | 5 ± 1 | 7 ± 2 | 8 ± 1 | 11 ± 4 |
| Average frequency | 0.9 ± 0.2 | 1.3 ± 0.1 | 1.4 ± 0.2 | 1.2 ± 0.1 |
| [scratches/μm] | | | | |

*sample size: 5 mm × 10 mm.
**all parameters were calculated using a Matlab code.

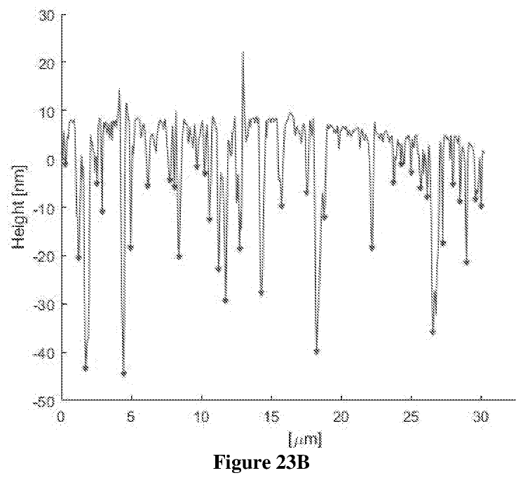

An image of the scratched surface and a line profile showing the scratch depth are shown in FIG. 23A and in FIG. 23B.

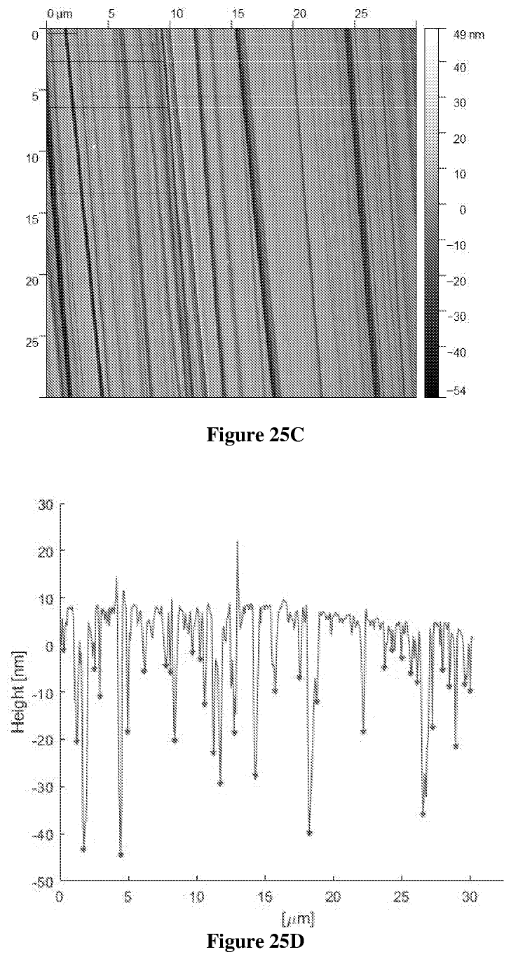

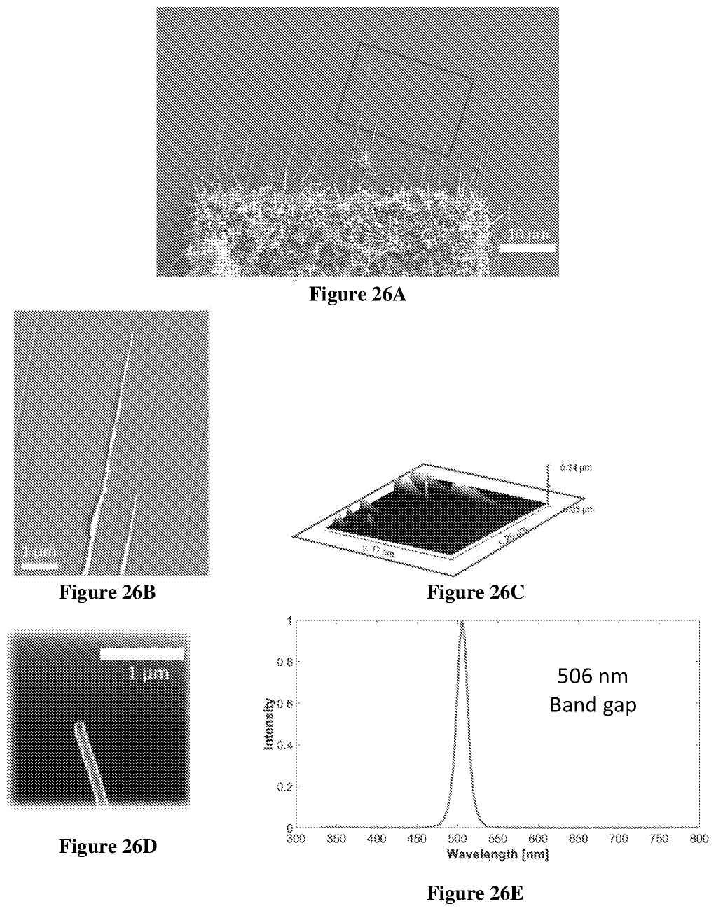

CdS nanowires were grown by chemical vapor deposition (CVD) on scratched substrates (substrates were Si/SiO₂; 300 nm oxide layer, polishing diamonds diameter=1 μm, substrates polished for 5 sec). In the growth tube, the substrate was held at a temperature range of 590° C. to 630° C., while the CdS powder was heated to a temperature of 830° C., see FIG. 24. The scratching parameters of the amorphous Si/SiO₂ substrate scratched at ˜20 N (FIG. 25C and FIG. 25D) were compared to a faceted single crystal substrate, an annealed M plane sapphire (FIG. 25A and FIG. 25B). FIG. 26 shows the growth of various CdS (II-IV SC) NWs on Si/SiO₂ scratched surfaces. FIG. 26A is an SEM image showing the NWs grown from 5 Å Au thin film on scratched SiO₂/Si surface (300 nm thermal oxide layer). FIG. 26B is a close up on two NWs. FIG. 26C is an AFM 3D image showing the nanowalls structure. FIG. 26D is an SEM image, a magnification of a CdS NW edge. FIG. 26E is a photoluminescence spectra of a single nanowire. The peak at 506 nm corresponds to the band gap of a CdS NW. Spectra was taken by irradiating with a 325 nm source.

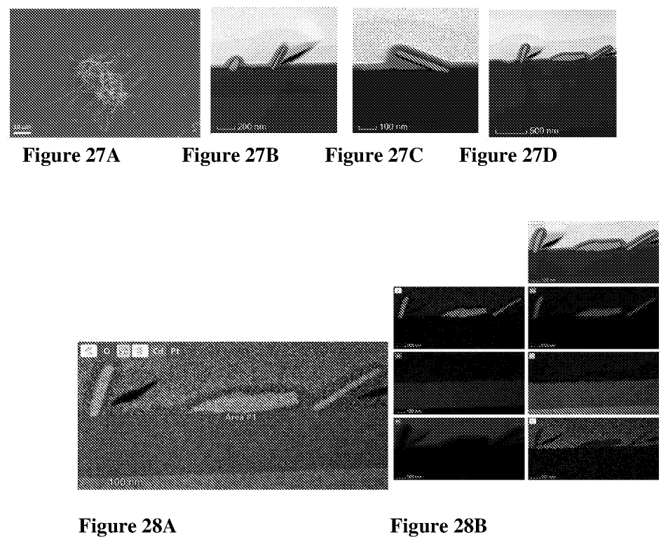

FIG. 27A is another SEM image showing the CdS NW grown on the Si/SiO₂ substrate. FIG. 27B, FIG. 27C and FIG. 27D are focused ion beam-transmission electron microscope (FIB-TEM) images showing the cross section of nanowires.

FIGS. 28A and 28B show elemental analysis of the NWs. Elemental analysis supports the chemical composition of the NWs. Note the various elements comprising the substrate (Si and O) and the elements comprising the NW (Cd and S) in the respective regions of the image. Pt and C can be seen as part of the coating layer applied on the sample in preparation for imaging. Table 4 include the percent of the various elements for a region of the NW (see rectangle in FIG. 28A). The similar fraction of Cd and S confirms the formation of a CdS nanowire.

TABLE 4
elemental analysis of a nanowire region

| | | | Atomic | Atomic | Mass | Mass | Fit |
|---|---|---|---|---|---|---|---|
| | | | Fraction | Error | Fraction | Error | error |
| Z | Element | Family | (%) | (%) | (%) | (%) | (%) |
| 8 | O | K | 5.66 | 1.00 | 1.33 | 0.14 | 3.81 |
| 16 | S | K | 48.15 | 12.24 | 22.62 | 4.75 | 0.38 |
| 48 | Cd | L | 46.19 | 9.62 | 76.06 | 11.53 | 0.30 |

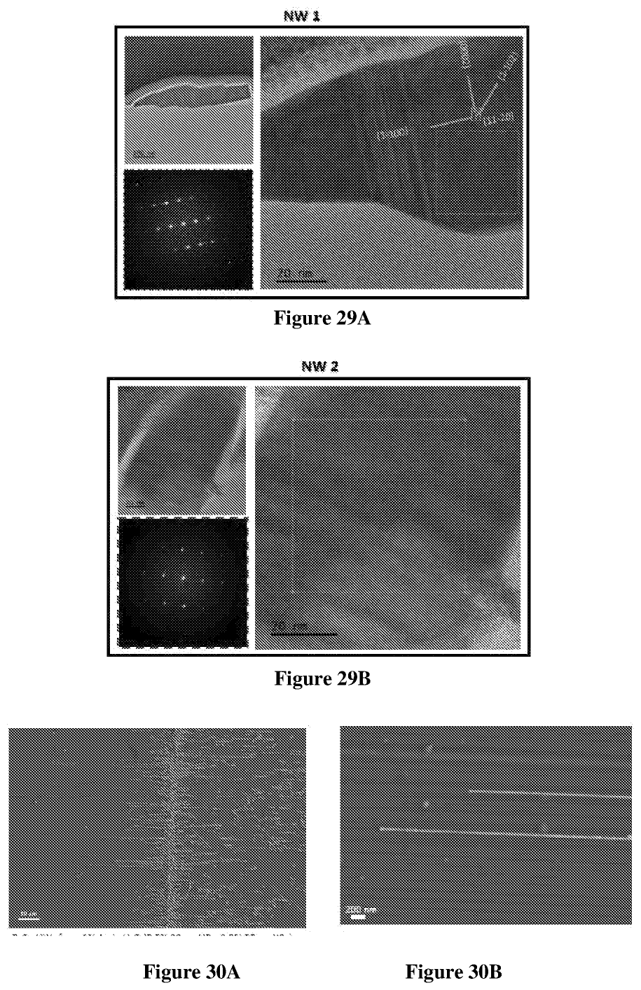

FIG. 29A and FIG. 29B are TEM images and data showing crystallographic analysis of two CdS nanowires (NW1 and NW2). The data supports single crystal structure of the nanowire. Top image on the left shows cross section of a wire. Right image is a higher magnification of the wire. Lower left image: FFT of the area shown in the right image.

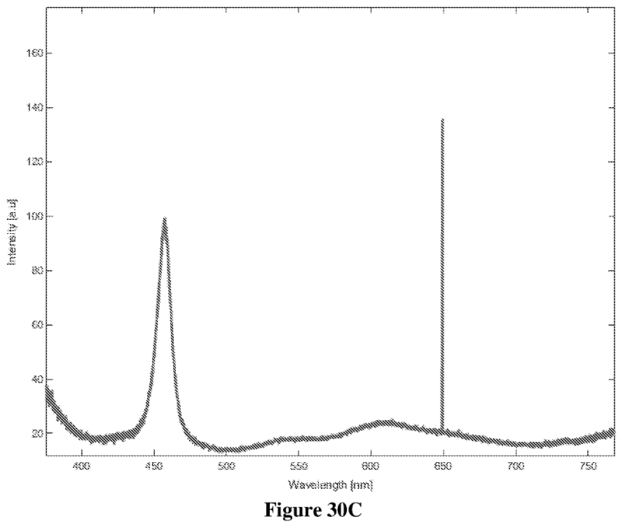

FIG. 30A is a SEM image showing the growth of zinc selenide NWs (ZnSe, II-VI SC) on a Si\SiO₂ substrate. ZnSe NWs were grown from Au nanoparticles. A solution of 1% Au nanoparticles in H₂O(0.5% 20 nm NPs+0.5% 50 nm NPs) was deposited on scratched Si/SiO₂ substrates (SiO₂ 300 nm thermal oxide layer) and dried. FIG. 30B is a higher magnification SEM image showing two NWs on the substrate. FIG. 30C is a photoluminescence spectra of a single nanowire. The peak at ˜450 nm is the expected photoluminescence from a zinc selenide wire. The line at ˜650 nm is the duplicate of the irradiating beam.

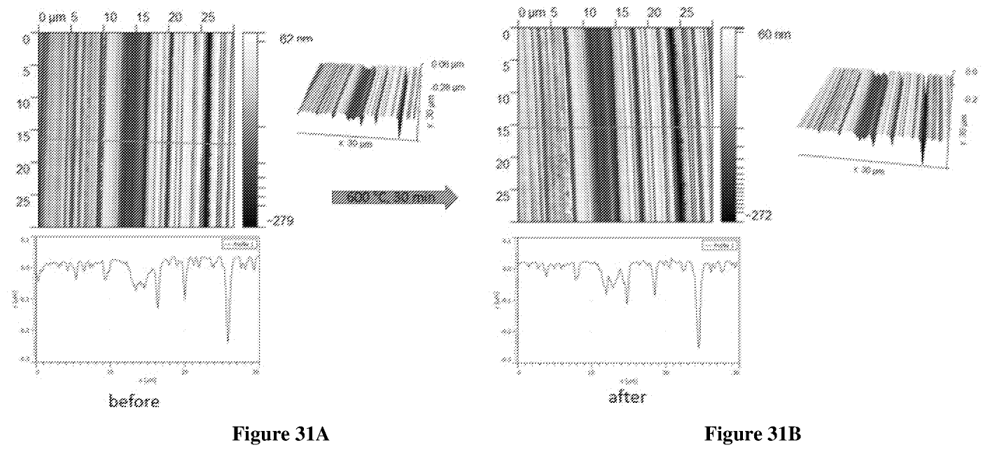

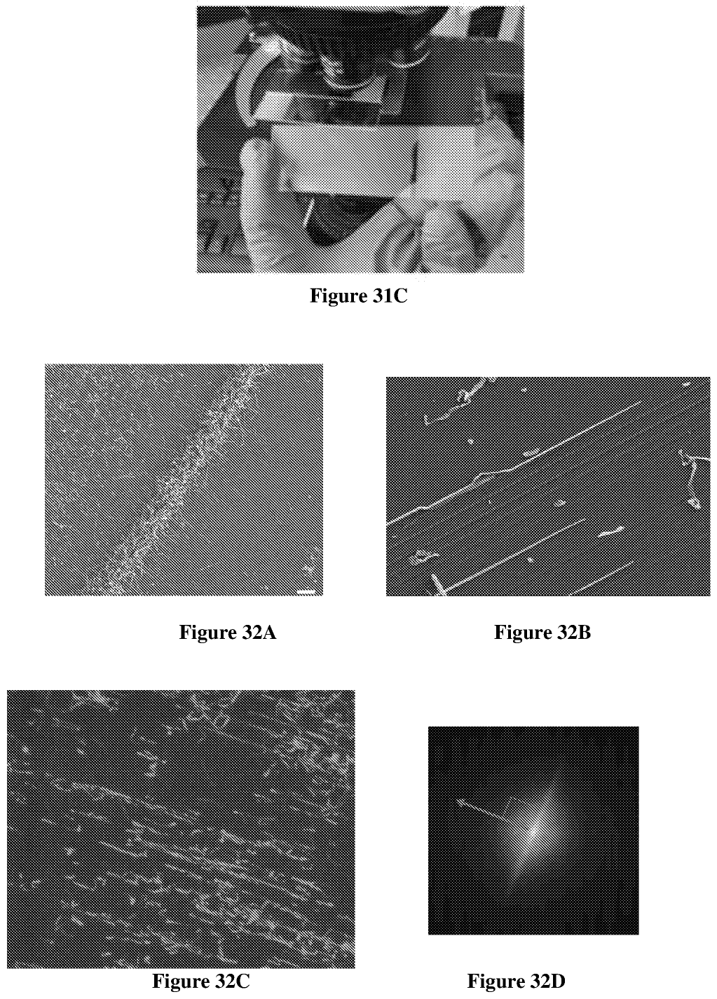

FIG. 31 shows scratched glass before and after annealing at 600° C. for 30 min. The glass used was a microscope slide, scratched at ˜20 N, 15 sec, using 30 μm diamonds.

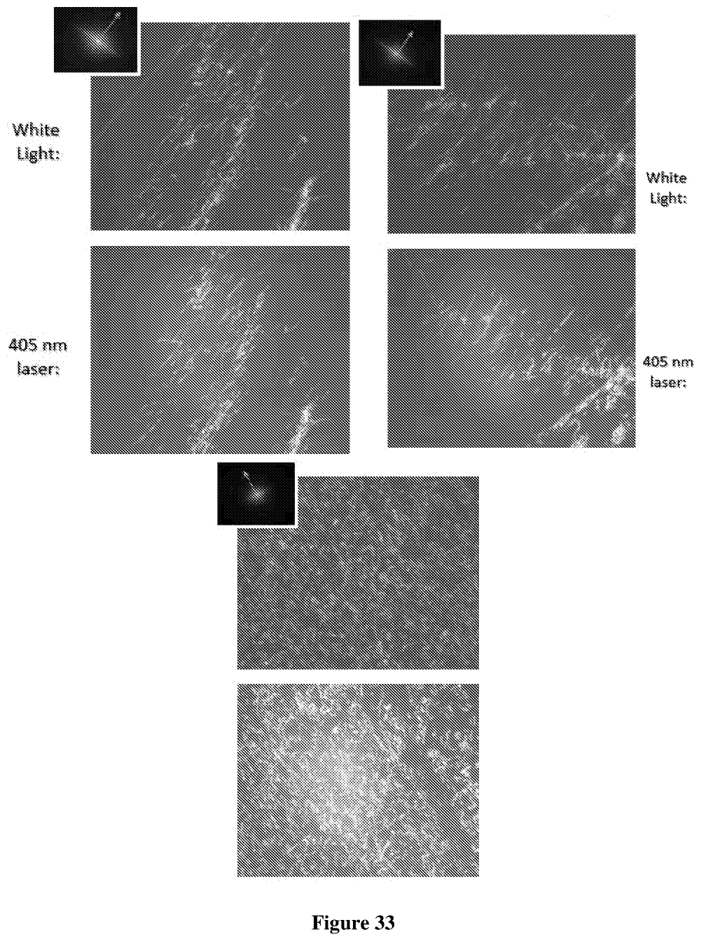

FIG. 32A shows two SEM images of CdS NWs. NWs growth was catalyzed by Au NP's deposited on the surface from a solution of 1% Au NPs in H₂O. FIG. 32B is an optical microscope image of CdS NWs catalyzed by evaporated Au. The image on the lower right corner is FFT. FIG. 33 is an optical microscope image of CdS NWs grown on scratched microscope slide. The top images were taken from substrates illuminated by white light. The bottom images were captured from substrates illuminated by 405 nm UV laser light.

### Example 5

### Guided Nanowires Grown on Glass using Alumina Templates

Substrates:

Glass substrates comprising nanogrooves (elongated shapes) were prepared using alumina templates. Alumina template surfaces comprising grooves were pressed against flat glass slides and heated. Upon heating, the glass flat surface changed its shape and follows the form of the grooves of the adjacent alumina. This results in a glass surface comprising grooves corresponding to the grooves on the alumina (see FIG. 34).

Annealed M-sapphire preparation: as-received well-cut unstable surface of α-Al₂O₃ M(101̅0) sapphire (Roditi International Corporation Ltd, England) was annealed at 1600° C. for 10 h. During the annealing process the unstable surface tends to reduce surface energy by rearranging into the most stable facets on the surface, in that case S and R. This leads to V-shape nanogrooves on the sapphire surface.

Imprint process: annealed M(101̅0) sapphire was attached to the surface of a clean soda-lime glass, microscope slide glass (Thermo scientific, New Hampshire 03801 U.S.A) and the two substrates were placed between two quartz slides with a weight of 4-4.5 g on top of them to apply small pressure (see FIG. 35B). Heavier weights can be used as well. The device was maintained at 590° C.-620° C. for about 1 hour, then cooled in air to room temperature.

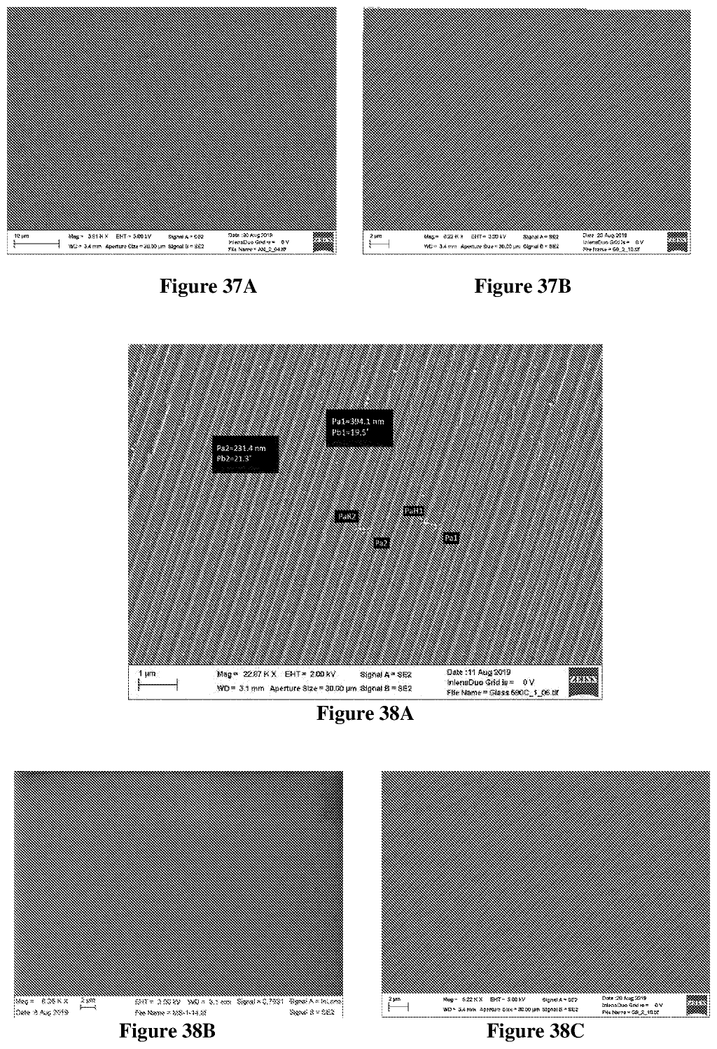

FIG. 36A shows the microscope slide before imprinting. FIG. 36B shows the microscope slide following imprint. The grooves can be seen in the imprinted area. The lower right area is an area that was not imprinted. FIG. 37 A is an image of an annealed M-plane sapphire surface used for imprinting on glass. FIG. 37B is a microscope slide following imprint using the M-plane sapphire.

FIG. 38A to FIG. 38C are samples of glass surfaces imprinted at various imprinting temperatures (FIG. 38A at 590° C., FIG. 38B at 600° C., FIG. 38C at 610° C.).

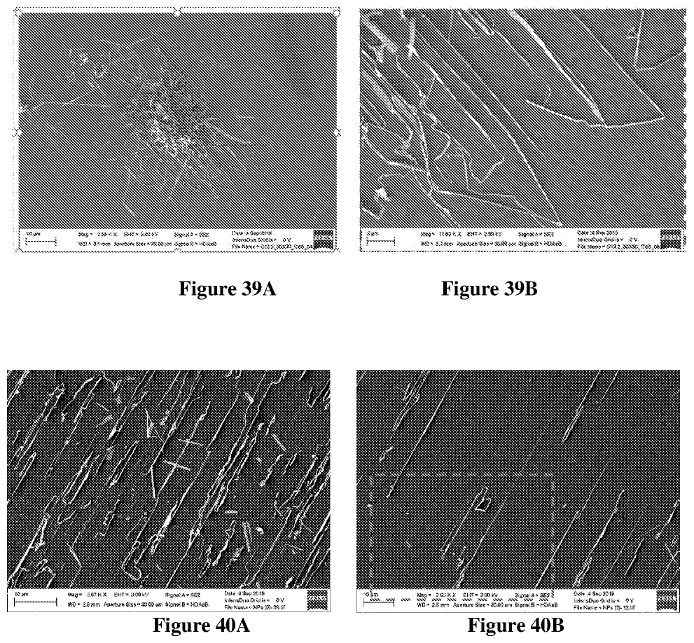

FIG. 39 shows NW growth on glass imprinted by M-plane grooved sapphire mold. The sample is a microscope slide imprinted using grooved sapphire, 5 Å Au evaporation was used for the formation of Au centers for NW growth. FIG. 39A is an SEM image showing guided growth of CdS nanowires & nanowalls on glass.; FIG. 39B is a magnification of the red dashed line in FIG. 39A, showing the alignment of the nanowires along the imprinted nanogrooves.

Guided nanowires were grown on the imprinted glass surfaces according to the procedure described herein above. FIG. 40: guided growth of CdS nanowires & nanowalls on soda-lime glass from gold nanoparticles, sample is microscope slide. The gold nanoparticles are deposited from a solution comprising 50 nm gold nanoparticles, solution is 1% NP suspension in water v:v (volume:volume). FIG. 40A is an SEM image showing guided growth of CdS nanowires; FIG. 40B an SEM image of another area showing guided growth of CdS nanowires.

As seen in the examples above, oriented NW growth on amorphous substrates was demonstrated. NW growth follows elongated structures formed on/in the surface of the substrates. NW growth is guided by the elongated structures on/in the surface. Different geometries/shaped of elongated structures can be used to form NW following a certain geometry/shape. The geometry of the elongated shape and of the NW formed next to it can be designed in view of the requirement of a certain applications.

In addition to the growth of NWs comprised of a single material, facile synthesis of core-shell NWs was also demonstrated. For example, the synthesis of site-controlled self-oriented n-CdS @p-Cu₂S core-shell nanowall horizontal arrays on insulating substrates was demonstrated, by the combination of vapor-phase surface-guided horizontal growth (for forming the core NWs) and solution-proceeded cation exchange reaction (for forming the shell). Consequently, an easy to scale-up method for fabrication of photovoltaic cells was demonstrated, based on core-shell nano structures. This method eliminates the need for postgrowth transfer, alignment and/or shell-etching steps. The open-circuit voltage and fill factor of exemplified demonstrated cells approach the best results ever reported for CdS-Cu₂S cells despite the low efficiency of light absorption. Further improvement of their energy conversion efficiency is expected. More importantly, the facile monolithic integration of microscale photovoltaic modules with parallel or series configuration is demonstrated, based on core-shell nanowall horizontal arrays. An open-circuit voltage up to 2.5 V was obtained from the tandem module with 4 unit cells connected in series. In view of the large open-circuit voltage and micro scale footprint of these modules, they are promising autonomous power sources for next-generation integrated nano-systems and the prevalent ultra-low power autonomous wireless electronics. Overall, the proposed route invokes a general strategy with potential applications for monolithic integration of functional nanodevices based on bottom-up 1D core-shell nano structures.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. An array of nanowires/nanowalls grown on a substrate, wherein:
said substrate is an amorphous substrate; or
said substrate is a polycrystalline substrate;
the surface of said substrate comprise elongated shapes;
the long dimension of said nanowires/nanowalls is parallel to the surface of said substrate;
the nanowires/nanowalls are located adjacent to said elongated shapes;
wherein said array is produced by a process comprising:
constructing an array of said elongated shapes on said substrate;
applying growth-catalyst material on a region of said elongated shapes;
exposing said substrate to a vapor, said vapor comprising:
atoms/ions required for nanowire/nanowall formation; and
carrier gas;
thereby forming said nanowires/nanowalls adjacent to said elongated shapes.

2. The array of claim 1, wherein the nanowires/nanowalls are parallel to each other.

3. The array of claim 1, wherein the length of said nanowires/nanowalls ranges between 1 nm and 1000 microns.

4. The array of claim 1, wherein the height of the nanowires/nanowalls ranges between 10 nm and 10 microns.

5. The array of claim 1, wherein the width of the nanowires/nanowalls ranges between 1 nm and 1 microns.

6. The array of claim 1, wherein the height/width aspect ratio of said nanowalls ranges between 50 and 1.

7. The array of claim 1, wherein said nanowires/nanowalls comprise GaN, CdSe, ZnSe, ZnS, CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb₂Te₃, Si, SiC, Ge, InGaN, AlGaN, MAPbX₃ and CsPbX₃ (X=Br, Cl, I).

8. The array of claim 1, wherein the spacing between adjacent nanowires/nanowalls of the array ranges between 10 nm and 10 μm.

9. The array of claim 1 wherein said substrate comprise silicon, silicon oxide or silicon coated by silicon oxide.

10. The array of claim 1, wherein the number of nanowires/nanowalls in the array ranges between 1 and 1,000,000 or between 1 and 1,000,000,000.

11. The array of claim 1, wherein at least one of said nanowires/nanowalls is a core-shell nanowire/nanowall or wherein at least one nanowire/nanowall comprises a core-shell section.

12. The array of claim 11, wherein said core comprises CdS and said shell comprises Cu₂S.

13. A photovoltaic (PV) device comprising:
the array of claim 1 wherein said nanowires/nanowalls comprise a core-shell section;
a. at least two electrical contacts connected to the wires such that a first contact is connected to the shell of the core-shell section of the wire and a second contact is connected to a non-shelled section of the wire.

14. A photovoltaic assembly, said assembly comprises at least two PV devices of claim 13.

15. The assembly of claim 14, wherein:
said at least two devices are electrically-connected in series such that the positive pole of a first device is connected to the negative pole of a second device; or wherein
said at least two devices are electrically-connected in parallel such that the positive pole of a first device is connected to the positive pole of a second device; or wherein
At least two devices are connected in series and at least two other devices are connected in parallel.

16. The photovoltaic device of claim 13, wherein the output voltage of said device/assembly is at least 0.7V.

17. The device or assembly of claim 16, wherein the output voltage of said cell is at least 1.5V, at least 2V or at least 3V, or wherein the output voltage ranges between 1V and 10V, 1V and 1.00V 1 V and 1000V, 1 V and 100,000V.

18. The photovoltaic device of claim 13, wherein current drawn from the device under illumination ranges between 1 pA and 1 μA or between 1 pA and 10 μA, or between 1 μA and 100 μA, or between 100 μA and 10 mA, or between 1 mA and 1 A, or between 1 mA and 100 A.

19. A method of generating voltage, generating current or a combination thereof, said method comprising:
providing the photovoltaic device of claim 13;
exposing said device to electromagnetic radiation, thereby generating voltage/current by said cell.

20. A method of photodetection, said method comprising:
providing the photovoltaic cell of claim 13;
exposing said cell to electromagnetic radiation, thereby generating voltage/current by said cell;
using said voltage/current as a detection signal for said radiation,

21. A method of producing an array of nanowires/nanowalls grown on a substrate, wherein:
said substrate is an amorphous substrate; or
said substrate is a polycrystalline substrate;
the surface of said substrate comprise elongated shapes;
the long dimension of said nanowires/nanowalls is parallel to the surface of said substrate;
the nanowires/nanowalls are located adjacent to said elongated shapes;
said method comprising:
constructing an array of elongated shapes on said substrate;
applying growth-catalyst material on a region of said elongated shapes;
exposing said substrate to a vapor, said vapor comprising:
atoms/ions required for nanowire/nanowall formation; and
a carrier gas;
thereby forming nanowires/nanowalls adjacent to, or on, or in said elongated shapes.

22. The method of claim 21, further comprising applying shells on a section of said nanowalls/nanowires, thus forming core-shell nanowires/nanowalls on said section.

23. The method of claim 22, wherein said step of applying shells comprises:
protecting sections of the wires using a deposited layer;
exposing said wires to a liquid solution comprising at least one atom/ion of the shell material, thereby forming a shell layer on the unprotected wire section(s).

24. The method of claim 22, wherein the shell layer is formed by cation-exchange reaction.

25. The method of claim 22, wherein the cation exchange reaction is performed in 0.05 M Cal ammonia solution (25% NH₃) at 50° C.

26. The method of claim 22, wherein,
the thickness of said shells ranges between 1 nm and 1 micron; and
the length of said core-shell section ranges between 10 nm and 1000 microns.

27. The method of claim 22, wherein said shell comprises Cu₂S, CdSe ZnSe, ZnS CdS, ZnTe, ZnO, PbS, PbSe, InN, GaP, InP, GaAs, InAs, InSb, ZnO, In₂O₃, TiO₂, SnO₂, Bi₂Te₃, Bi₂Se₃, Sb2Te3, Si, SiC, Ge, InGaN, AlGaN, MAPbX₃ and CsPbX3 (X=Br, Cl, I).

28. The method of claim 21, wherein said nanowires/nanowalls are in contact with said elongated shapes,

29. The method of claim 21, wherein said elongated shapes are in the form of grooves, steps, ridges, trenches or channels.

30. The method of claim 21, wherein said elongated shapes are constructed using photolithography, imprint lithography, electron beam lithography, surface scratching or any combination thereof.

31. The method of claim 21, wherein said elongated shapes are constructed by mechanical rubbing, scratching or polishing using an abrasive material.

32. The method of claim 21, wherein the dimensions of the elongated shapes are:
Height ranging between 5 nm and 10 microns;
Width ranging between 10 nm and 10 microns;
Length ranging between 10 nm and 1000 microns;
Spacing between two adjacent shapes ranging between 10 nm and 10 microns.

33. The method of claim 21, wherein the number of nanowires/nanowalls in the array ranges between 1 and 1,000,000.

34. The method of claim 21, wherein the elongated shapes are parallel to each other.

35. The method of claim 21, wherein the formed nanowires/nanowalls are parallel to each other.

36. A method of producing a photovoltaic device, said method comprising:
constructing an array of elongated shapes on a substrate;
applying growth-catalyst material on a region of said elongated shapes;
exposing said substrate to a vapor, said vapor comprising
atoms/ions required for nanowire/nanowall formation; and
carrier gas;
thereby forming nanowires/nanowalls adjacent to said elongated shapes:
applying shells on a section of said nanowires/nanowalls, thus forming core-shell nanowires/nanowalls on said section;
applying at least two electrical contacts to said device such that a first contact is applied on and in contact with the shell of a core-shell wire section and a second contact is applied on a non-shelled section of said wire;
wherein:
said substrate is an amorphous substrate; or
said substrate is a polycrystalline substrate;
the long dimension of said formed nanowires/nanowalls is parallel to the surface of said substrate;

37. The method of claim 36, wherein said step of applying shells comprises:
protecting sections of the wires using a deposited layer;
exposing said wires to a liquid solution comprising at least one atom/ion of the shell material, thereby forming a shell layer on the unprotected wire section(s).

38. The method of claim 36, wherein said contacts are applied using photolithography and metal evaporation.

39. The method of claim 36, wherein said contacts are connected to a load, to an electrical measurement device or to a combination thereof.

40. The method of claim 36, wherein an electrical contact area on said substrate/nanowires is defined by photolithography and wherein metal evaporation is conducted into said defined areas.

41. The method of claim 36, wherein said electrical contacts comprise Au or Cr/Au.

42. The method of claim 36, wherein the thickness of said contacts ranges between 100 nm and 1000 nm.

43. The method of claim 36, wherein a portion of said electrical contacts is deposited in a shape of elongated stripes, the long axis of said stripes is deposited perpendicular to the long axis of said nanowires/nanowalls.
